(19) United States
(12) Patent Application Publication
(10) Pub. No.: US 2024/0250505 A1
(43) Pub. Date: Jul. 25, 2024

(54) NITRIDE SEMICONDUCTOR LIGHT-EMITTING ELEMENT

(71) Applicant: Nuvoton Technology Corporation Japan, Kyoto (JP)

(72) Inventor: Toru TAKAYAMA, Toyama (JP)

(21) Appl. No.: 18/583,558

(22) Filed: Feb. 21, 2024

Related U.S. Application Data
(63) Continuation-in-part of application No. PCT/JP2022/030468, filed on Aug. 9, 2022.

(30) Foreign Application Priority Data
Aug. 24, 2021 (JP) 2021-136709

(51) Int. Cl. H01S 5/22; H01S 5/042; H01S 5/343; H01S 5/40

(52) U.S. Cl. CPC H01S 5/22; H01S 5/04252; H01S 5/34333; H01S 5/34346; H01S 5/4031

(57) ABSTRACT

A nitride semiconductor light-emitting element includes: an N-type first cladding layer; an N-side guide layer; an active layer that includes a well layer and a barrier layer, and has a quantum well structure; a P-side guide layer; and a P-type cladding layer. A band gap energy of the N-side guide layer monotonically increases with increasing distance from the active layer, the N-side guide layer includes a portion in which the band gap energy continuously increases with increasing distance from the active layer, an average band gap energy of the P-side guide layer is larger than or equal to an average band gap energy of the N-side guide layer, and Tn<Tp, where Tn is a thickness of the N-side guide layer and Tp is a thickness of the P-side guide layer.

### CROSS REFERENCE TO RELATED APPLICATIONS

This is a continuation-in-part application of PCT International Application No. PCT/JP2022/030468 filed on Aug. 9, 2022, designating the United States of America, which is based on and claims priority of Japanese Patent Application No. 2021-136709 filed on Aug. 24, 2021. The entire disclosures of the above-identified applications, including the specifications, drawings, and claims are incorporated herein by reference in their entirety.

### FIELD

The present disclosure relates to nitride semiconductor light-emitting elements.

### BACKGROUND

Conventionally, nitride semiconductor light-emitting elements have been used as light sources in, for example, processing equipment. There is a demand for increased output and efficiency in light sources used in processing equipment.

One known technique for increasing the efficiency of nitride semiconductor light-emitting elements is to reduce the operating voltage (for example, see Patent Literature (PTL) 1).

### CITATION LIST

### Patent Literature

PTL 1: Japanese Unexamined Patent Application Publication No. 2018-50021

### SUMMARY

### Technical Problem

In nitride semiconductor light-emitting elements, in addition to the technique described in PTL 1, reducing the thickness of the P-type cladding layer is effective in reducing the operating voltage. However, reducing the thickness of the P-type cladding layer moves the peak of the light intensity distribution in the stacking direction (i.e., the direction perpendicular to the principal surface of each semiconductor layer) toward the N-type cladding layer from the active layer. This reduces the optical confinement factor indicating the degree of optical confinement into the active layer, which in turn reduces the thermal saturation level of the light output. It is therefore difficult to achieve a high-output nitride semiconductor light-emitting element.

The present disclosure solves such problems and has an object to provide a nitride semiconductor light-emitting element with reduced operating voltage and an increased optical confinement factor into the active layer.

### Solution to Problem

In order to overcome the above problem, a nitride semiconductor light-emitting element according to one aspect of the present disclosure includes a semiconductor stack and emits light from an end face of the semiconductor stack, the end face being perpendicular to a stacking direction of the semiconductor stack. In the nitride semiconductor light-emitting element, the semiconductor stack includes: an N-type first cladding layer; an N-side guide layer disposed above the N-type first cladding layer; an active layer that is disposed above the N-side guide layer, includes a well layer and a barrier layer, and has a quantum well structure; a P-side guide layer disposed above the active layer; an electron barrier layer disposed above the P-side guide layer; and a P-type cladding layer disposed above the electron barrier layer, the P-side guide layer is an undoped layer, a band gap energy of the N-side guide layer monotonically increases with increasing distance from the active layer, the N-side guide layer includes a portion in which the band gap energy continuously increases with increasing distance from the active layer, an average band gap energy of the P-side guide layer is larger than or equal to an average band gap energy of the N-side guide layer, Tn<Tp, where Tn is a thickness of the N-side guide layer and Tp is a thickness of the P-side guide layer, and a band gap energy of the barrier layer is less than or equal to a minimum value of the band gap energy of the N-side guide layer and a minimum value of a band gap energy of the P-side guide layer.

In order to overcome the above problem, a nitride semiconductor light-emitting element according to another aspect of the present disclosure includes a semiconductor stack and emits light from an end face of the semiconductor stack, the end face being perpendicular to a stacking direction of the semiconductor stack. In the nitride semiconductor light-emitting element, the semiconductor stack includes: an N-type first cladding layer; an N-side guide layer disposed above the N-type first cladding layer; an active layer that is disposed above the N-side guide layer, includes a well layer and a barrier layer, and has a quantum well structure; a P-side guide layer disposed above the active layer; an electron barrier layer disposed above the P-side guide layer; and a P-type cladding layer disposed above the electron barrier layer, the P-side guide layer is an undoped layer, a band gap energy of the N-side guide layer monotonically increases with increasing distance from the active layer, the N-side guide layer includes a portion in which the band gap energy continuously increases with increasing distance from the active layer, an average band gap energy of the P-side guide layer is larger than an average band gap energy of the N-side guide layer, and a band gap energy of the barrier layer is less than or equal to a minimum value of the band gap energy of the N-side guide layer and a minimum value of a band gap energy of the P-side guide layer.

In order to overcome the above problem, a nitride semiconductor light-emitting element according to yet another aspect of the present disclosure includes a semiconductor stack and emits light from an end face of the semiconductor stack, the end face being perpendicular to a stacking direction of the semiconductor stack. In the nitride semiconductor light-emitting element, the semiconductor stack includes: an N-type first cladding layer; an N-side guide layer disposed above the N-type first cladding layer; an active layer that is disposed above the N-side guide layer, includes a well layer and a barrier layer, and has a quantum well structure; a P-side guide layer disposed above the active layer; an electron barrier layer disposed above the P-side guide layer; and a P-type cladding layer disposed above the electron barrier layer, the P-side guide layer is an undoped layer, a band gap energy of the N-side guide layer monotonically increases with increasing distance from the active layer, the N-side guide layer includes a portion in which the band gap energy continuously increases with increasing distance from the active layer. The nitride semiconductor light-emitting element comprises a P-side electrode disposed above the semiconductor stack, and the P-side electrode includes Ag.

### Advantageous Effects

The present disclosure can provide a nitride semiconductor light-emitting element with reduced operating voltage and an increased optical confinement factor indicating the degree of optical confinement into the active layer.

### BRIEF DESCRIPTION OF DRAWINGS

The present disclosure can provide a nitride semiconductor light-emitting element with reduced operating voltage and an increased optical confinement factor indicating the degree of optical confinement into the active layer.

FIG. 1 is a schematic plan view of the overall configuration of a nitride semiconductor light-emitting element according to Embodiment 1.

FIG. 2A is a cross-sectional view of the overall configuration of the nitride semiconductor light-emitting element according to Embodiment 1.

FIG. 2B is a schematic cross-sectional view illustrating the configuration of an active layer included in the nitride semiconductor light-emitting element according to Embodiment 1.

FIG. 3 is a schematic diagram outlining the light intensity distribution in the stacking direction of the nitride semiconductor light-emitting element according to Embodiment 1.

FIG. 4 is a graph illustrating coordinates of positions in the stacking direction of the nitride semiconductor light-emitting element according to Embodiment 1.

FIG. 5 is a schematic graph illustrating a band gap energy distribution in the active layer and layers in the vicinity thereof in the nitride semiconductor light-emitting element according to Embodiment 1.

FIG. 6 illustrates graphs illustrating refractive index distributions and light intensity distributions in the stacking direction of nitride semiconductor light-emitting elements according to Comparative Examples 1 to 3 and the nitride semiconductor light-emitting element according to Embodiment 1.

FIG. 7 illustrates graphs illustrating simulation results of distributions of valence band electric potentials and hole Fermi levels in the stacking direction of the nitride semiconductor light-emitting elements according to Comparative Examples 1 to 3 and the nitride semiconductor light-emitting element according to Embodiment 1.

FIG. 8 illustrates graphs illustrating simulation results of distributions of carrier concentrations in the stacking direction of the nitride semiconductor light-emitting elements according to Comparative Examples 1 to 3 and the nitride semiconductor light-emitting element according to Embodiment 1.

FIG. 9 is a graph illustrating simulation results of the relationship between an average In composition ratio of an N-side guide layer and an optical confinement factor (Γv) according to Embodiment 1.

FIG. 10 is a graph illustrating simulation results of the relationship between an average In composition ratio of the N-side guide layer and an operating voltage according to Embodiment 1.

FIG. 11 illustrates graphs illustrating the relationships of a position in the stacking direction of the nitride semiconductor light-emitting element according to Comparative Example 3 with a piezo polarization charge density, a piezo polarization electric field, and a conduction band electric potential.

FIG. 12 illustrates graphs each illustrating the relationship of a position in the stacking direction of the nitride semiconductor light-emitting element according to Embodiment 1 with a piezo polarization charge density, a piezo polarization electric field, and a conduction band electric potential.

FIG. 13 illustrates graphs each illustrating simulation results of the relationship between an average In composition ratio of the N-side guide layer of the nitride semiconductor light-emitting element and an optical confinement factor (Γv) according to Embodiment 1.

FIG. 14 illustrates graphs each illustrating simulation results of the relationship between an average In composition ratio of the N-side guide layer of the nitride semiconductor light-emitting element and waveguide loss according to Embodiment 1.

FIG. 15 illustrates graphs each illustrating simulation results of the relationship between an average In composition ratio of the N-side guide layer of the nitride semiconductor light-emitting element and an operating voltage according to Embodiment 1.

FIG. 16 is a graph illustrating simulation results of the relationship between a thickness of the N-side guide layer and position P1 according to Embodiment 1.

FIG. 17 is a graph illustrating simulation results of the relationship between a thickness of the N-side guide layer and difference ΔP according to Embodiment 1.

FIG. 18 is a graph illustrating simulation results of the relationship between the thickness of a P-type cladding layer and an optical confinement factor (Γv) according to Embodiment 1.

FIG. 19 is a graph illustrating simulation results of the relationship between the thickness of the P-type cladding layer and waveguide loss according to Embodiment 1.

FIG. 20 is a graph illustrating simulation results of the relationship between the thickness of the P-type cladding layer and effective refractive index difference ΔN according to Embodiment 1.

FIG. 21 is a graph illustrating simulation results of the relationship between the thickness of the P-type cladding layer and position P1 according to Embodiment 1.

FIG. 22 is a graph illustrating simulation results of the relationship between the thickness of a P-type cladding layer and difference ΔP according to Embodiment 2.

FIG. 23A is a schematic cross-sectional view of the overall configuration of a nitride semiconductor light-emitting element according to Embodiment 2.

FIG. 23B is a schematic cross-sectional view illustrating the configuration of an active layer included in the nitride semiconductor light-emitting element according to Embodiment 2.

FIG. 24 is a schematic graph illustrating a band gap energy distribution in the active layer and layers in the vicinity thereof in the nitride semiconductor light-emitting element according to Embodiment 2.

FIG. 25 is a schematic cross-sectional view of the overall configuration of a nitride semiconductor light-emitting element according to Embodiment 3.

FIG. 26 is a schematic graph illustrating a band gap energy distribution in the active layer and layers in the vicinity thereof in the nitride semiconductor light-emitting element according to Embodiment 3.

FIG. 27 is a schematic cross-sectional view of the overall configuration of a nitride semiconductor light-emitting element according to Embodiment 4.

FIG. 28 is a schematic graph illustrating a band gap energy distribution in the active layer and layers in the vicinity thereof in the nitride semiconductor light-emitting element according to Embodiment 4.

FIG. 29 is a graph illustrating simulation results of the relationship between an average In composition ratio of an N-side guide layer and an optical confinement factor (Γv) according to Embodiment 4.

FIG. 30 is a graph illustrating simulation results of the relationship between the average In composition ratio of the N-side guide layer and waveguide loss according to Embodiment 4.

FIG. 31 is a graph illustrating simulation results of the relationship between the average In composition ratio of the N-side guide layer and an operating voltage according to Embodiment 4.

FIG. 32 is a graph illustrating simulation results of the relationship between the average In composition ratio of the N-side guide layer and position P1 according to Embodiment 4.

FIG. 33 is a graph illustrating simulation results of the relationship between the average In composition ratio of the N-side guide layer and difference ΔP according to Embodiment 4.

FIG. 34 is a schematic cross-sectional view of the overall configuration of a nitride semiconductor light-emitting element according to Embodiment 5.

FIG. 35 is a schematic cross-sectional view of the overall configuration of a nitride semiconductor light-emitting element according to Embodiment 6.

FIG. 36A is a schematic cross-sectional view of the overall configuration of a nitride semiconductor light-emitting element according to Embodiment 7.

FIG. 36B is a schematic cross-sectional view illustrating the configuration of an active layer included in the nitride semiconductor light-emitting element according to Embodiment 7.

FIG. 37 is a schematic cross-sectional view of the overall configuration of a nitride semiconductor light-emitting element according to Embodiment 8.

FIG. 38 is a schematic graph illustrating a band gap energy distribution in the active layer and layers in the vicinity thereof in the nitride semiconductor light-emitting element according to Embodiment 8.

FIG. 39A is a schematic cross-sectional view of the overall configuration of a nitride semiconductor light-emitting element according to Embodiment 9.

FIG. 39B is a schematic cross-sectional view illustrating the configuration of an active layer included in the nitride semiconductor light-emitting element according to Embodiment 9.

FIG. 40 is a schematic graph illustrating a band gap energy distribution in the active layer and layers in the vicinity thereof in the nitride semiconductor light-emitting element according to Embodiment 9.

FIG. 41 is a schematic graph illustrating a band gap energy distribution in the active layer and layers in the vicinity thereof in the nitride semiconductor light-emitting element according to Variation 1 of Embodiment 9.

FIG. 42 is a schematic graph illustrating a band gap energy distribution in the active layer and layers in the vicinity thereof in the nitride semiconductor light-emitting element according to Variation 2 of Embodiment 9.

FIG. 43 is a schematic cross-sectional view of the overall configuration of the nitride semiconductor light-emitting element according to Variation 1.

FIG. 44 is a schematic cross-sectional view of the overall configuration of the nitride semiconductor light-emitting element according to Variation 2.

### DESCRIPTION OF EMBODIMENTS

Hereinafter, embodiments of the present disclosure will be described with reference to the drawings. It should be noted that each of the embodiments described below shows a specific example of the present disclosure. Therefore, numerical values, shapes, materials, structural components, the arrangement and connection of the structural components, etc. indicated in the following embodiments are mere examples, and are not intended to limit the scope of the present disclosure.

In addition, each of the diagrams is a schematic diagram and thus is not necessarily strictly illustrated. Therefore, the scale sizes and the like are not necessarily exactly represented in each of the diagrams. In each of the diagrams, substantially the same structural components are assigned with the same reference signs, and redundant descriptions will be omitted or simplified.

Moreover, in the present specification, the terms “above” and “below” do not refer to the vertically upward direction and vertically downward direction in terms of absolute spatial recognition, but are used as terms defined by relative positional relationships based on the layering order in a layered configuration. Furthermore, the terms “above” and “below” are applied not only when two structural components are disposed with a gap therebetween or when a separate structural component is interposed between two structural components, but also when two structural components are disposed in contact with each other.

### Embodiment 1

The nitride semiconductor light-emitting element according to Embodiment 1 will be described.

### 1-1. Overall Configuration

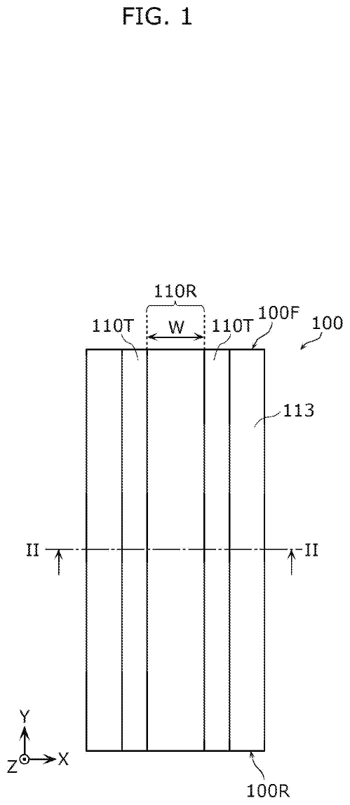

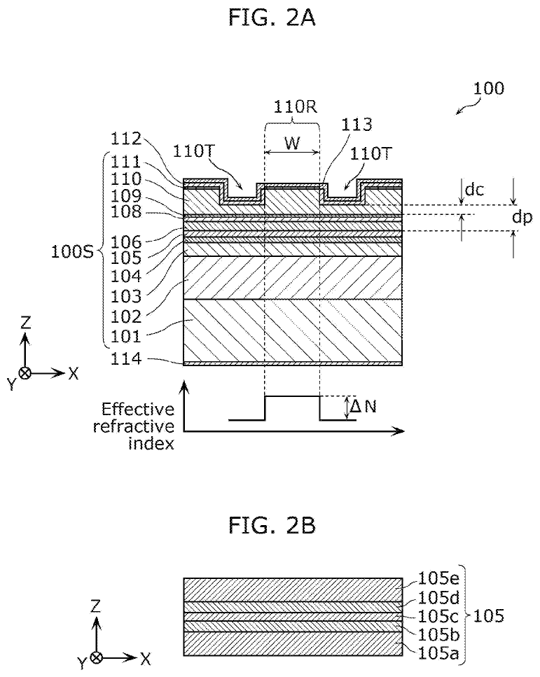

First, the overall configuration of the nitride semiconductor light-emitting element according to the present embodiment will be described with reference to FIG. 1, FIG. 2A, and FIG. 2B. FIG. 1 and FIG. 2A are a schematic plan view and a cross-sectional view, respectively, of the overall configuration of nitride semiconductor light-emitting element 100 according to the present embodiment. FIG. 2A illustrates a cross section taken at line II-II in FIG. 1. FIG. 2B is a schematic cross-sectional view illustrating the configuration of active layer 105 included in nitride semiconductor light-emitting element 100 according to the present embodiment. Note that, in the diagrams, X-, Y-, and Z-axes that are orthogonal to each other are illustrated. The X-, Y-, and Z-axes are oriented in a right-handed Cartesian coordinate system. The stacking direction of nitride semiconductor light-emitting element 100 is parallel to the Z-axis direction, and the main emission direction of the light (laser beam) is parallel to the Y-axis direction.

As illustrated in FIG. 2A, nitride semiconductor light-emitting element 100 includes semiconductor stack 100S including nitride semiconductor layers, and emits light from end face 100F (see FIG. 1), of semiconductor stack 100S, that is perpendicular to the stacking direction (i.e., the Z-axis direction). In the present embodiment, nitride semiconductor light-emitting element 100 is a semiconductor laser element including two end faces, 100F and 100R, forming a resonator. End face 100F is the front end face that emits the laser beam, and end face 100R is the rear end face that is more reflective than end face 100F. In the present embodiment, the reflectance of end face 100F is 16% and the reflectance of end face 100R is 95%. The resonator length (i.e., the distance between end face 100F and end face 100R) of nitride semiconductor light-emitting element 100 according to the present embodiment is approximately 1200 μm.

As illustrated in FIG. 2A, nitride semiconductor light-emitting element 100 includes semiconductor stack 100S, current blocking layer 112, P-side electrode 113, and N-side electrode 114. Semiconductor stack 100S includes substrate 101, N-type first cladding layer 102, N-type second cladding layer 103, N-side guide layer 104, active layer 105, P-side guide layer 106, intermediate layer 108, electron barrier layer 109, P-type cladding layer 110, and contact layer 111.

Substrate 101 is a plate-shaped member that serves as the base of nitride semiconductor light-emitting element 100. In the present embodiment, substrate 101 is an N-type GaN substrate.

N-type first cladding layer 102 is one example of an N-type cladding layer disposed above substrate 101. N-type first cladding layer 102 is a layer with a smaller refractive index and a larger band gap energy than active layer 105. In the present embodiment, N-type first cladding layer 102 is an N-type Al_{0.035}Ga_{0.965}N layer with a thickness of 1200 nm. N-type first cladding layer 102 is doped with Si at a concentration of 1×10¹⁸ cm⁻³ as an impurity.

N-type second cladding layer 103 is one example of an N-type cladding layer disposed above substrate 101. In the present embodiment, N-type second cladding layer 103 is disposed above N-type first cladding layer 102. N-type second cladding layer 103 is a layer with a smaller refractive index and a larger band gap energy than active layer 105. In the present embodiment, N-type second cladding layer 103 is an N-type GaN layer with a thickness of 100 nm. N-type second cladding layer 103 is doped with Si at a concentration of 1×10¹⁸ cm⁻³ as an impurity. The band gap energy of N-type second cladding layer 103 is smaller than the band gap energy of N-type first cladding layer 102 and larger than or equal to the maximum value of the band gap energy of P-side guide layer 106.

N-side guide layer 104 is an optical guide layer disposed above N-type second cladding layer 103. N-side guide layer 104 has a larger refractive index and a smaller band gap energy than N-type first cladding layer 102 and N-type second cladding layer 103. In N-side guide layer 104, a band gap energy monotonically increases with increasing distance from active layer 105 (i.e., with decreasing distance from N-type first cladding layer 102 in the inverse direction of the crystal-grow direction of each of the semiconductor layers). Here, a configuration in which a band gap energy monotonically increases includes a configuration in which a region where a band gap energy is constant in the stacking direction is present. N-side guide layer 104 includes a portion in which a band gap energy continuously increases with increasing distance from active layer 105. Here, a configuration in which a band gap energy continuously and monotonically increases in the stacking direction does not include a configuration in which a band gap energy discontinuously changes in the stacking direction. According to the present disclosure, the configuration in which a band gap energy continuously and monotonically increases means a configuration in which a discontinuous increase in a band gap energy at a certain position is less than 2% of the band gap energy at the certain position. For example, the configuration in which a band gap energy continuously and monotonically increases with increasing distance from active layer 105 in N-side guide layer 104 means a configuration in which, based on a band gap energy at a certain position in N-side guide layer 104, an amount of increase in a band gap energy at a position shifted by a minute distance from the certain position in an inverse direction of the crystal-grow direction is less than 2% of the magnitude of the band gap energy at the certain position. For example, the configuration in which the band gap energy continuously and monotonically increases does not include a configuration in which a band gap energy increases stepwise by at least 2% in an inverse direction of the stacking direction, but includes a configuration in which a band gap energy increases stepwise by less than 2% in the stacking direction. Although a band gap energy continuously increases with increasing distance from active layer 105 in the entire N-side guide layer 104 according to the present embodiment, the configuration of N-side guide layer 104 is not limited to this configuration. For example, a proportion of the thickness of a portion of N-side guide layer 104 having a band gap energy that continuously increases with increasing distance from active layer 105 may be at least 50% of the thickness of entire N-side guide layer 104. Alternatively, the proportion may be 70% or more, or may be 90% or more.

Here, an amount of increase in a band gap energy of N-side guide layer 104 in the direction toward N-type second cladding layer 103 (the inverse direction of the crystal-grow direction) is assumed to be ΔEgn. The amount of increase in a band gap energy of N-side guide layer 104 in the inverse direction of the crystal-grow direction is defined by a difference between a band gap energy of N-side guide layer 104 at an interface on the side closer to active layer 105 and a band gap energy of N-side guide layer 104 at an interface on the side closer to N-type second cladding layer 103. A percentage of the magnitude of a band gap energy that continuously increases may be 70% or more of ΔEgn. The percentage may be 80% or more, or may be 90% or more. As described above, by increasing the band gap energy of N-side guide layer 104 in the inverse direction of the crystal-grow direction, the refractive index of N-side guide layer 104 continuously and monotonically increases with decreasing distance from active layer 105. In this case, since the refractive index of N-side guide layer 104 increases with decreasing distance from active layer 105, the peak of the light intensity distribution in the stacking direction can be located closer to active layer 105. Here, if ΔEgn is small, the effect is small. Conversely, if it is too large, the light generated from active layer 105 is absorbed in a region of N-side guide layer 104 with a small band gap energy adjacent to active layer 105, resulting in an increase in waveguide loss. In order to inhibit such waveguide loss, ΔEgn may be at least 100 meV and at most 400 meV.

When N-side guide layer 104 includes InXnGa_{1-Xn}N, In composition ratio Xn of N-side guide layer 104 monotonically decreases with increasing distance from active layer 105. With this, the band gap energy of N-side guide layer 104 monotonically increases with increasing distance from active layer 105. Here, the configuration in which In composition ratio Xn monotonically decreases includes a configuration in which a region where In composition ratio Xn is constant is present. N-side guide layer 104 includes a portion in which In composition ratio continuously decreases with increasing distance from active layer 105. Here, the configuration in which In composition ratio Xn continuously and monotonically decreases does not include a configuration in which In composition ratio Xp discontinuously changes in the stacking direction. The configuration in which In composition ratio Xn continuously and monotonically decreases means a configuration in which an amount of discontinuous decrease in In composition ratio Xn at a certain position of N-side guide layer 104 in the stacking direction is less than 20% of In composition ratio Xn at the certain position.

An average band gap energy of N-side guide layer 104 is less than or equal to an average band gap energy of P-side guide layer 106. In other words, an average value of In composition ratio of N-side guide layer 104 is greater than or equal to an average value of In composition ratio of P-side guide layer 106. In the present embodiment, an average value of In composition ratio of N-side guide layer 104 is identical to an average value of In composition ratio of P-side guide layer 106. In other words, an average band gap energy of N-side guide layer 104 is identical to an average band gap energy of P-side guide layer 106. In addition, Tn<Tp (Expression 1), where Tn is a thickness of N-side guide layer 104 and Tp is a thickness of P-side guide layer 106.

In addition, the maximum value of In composition ratio in N-side guide layer 104 is less than or equal to In composition ratio of each of the barrier layers.

In the present embodiment, N-side guide layer 104 is an N-type In_{Xn}Ga_{1-Xn}N layer with a thickness of 160 nm. N-side guide layer 104 is doped with Si at a concentration of 3×10¹⁷ cm⁻³ as an impurity. More specifically, the composition of N-side guide layer 104 at and in the vicinity of the interface closer to active layer 105 is In_{0.04}Ga_{0.96}N, and the composition at and in the vicinity of the interface farther from active layer 105 is GaN. In composition ratio Xn of N-side guide layer 104 decreases at a constant change rate with increasing distance from active layer 105.

Active layer 105 is a light-emitting layer disposed above N-side guide layer 104 and has a quantum well structure. As illustrated in FIG. 2B, in the present embodiment, active layer 105 includes well layers 105b and 105d and barrier layers 105a, 105c, and 105e.

Barrier layer 105a is disposed above N-side guide layer 104 and functions as a barrier in the quantum well structure. In the present embodiment, barrier layer 105a is an undoped In_{0.05}Ga_{0.95}N layer with a thickness of 7 nm.

Well layer 105b is disposed above barrier layer 105a and functions as a well in the quantum well structure. Well layer 105b is disposed between barrier layer 105a and barrier layer 105c. In the present embodiment, well layer 105b is an undoped In_{0.18}Ga_{0.82}N layer with a thickness of 3 nm.

Barrier layer 105c is disposed above well layer 105b and functions as a barrier in the quantum well structure. In the present embodiment, barrier layer 105c is an undoped In_{0.05}Ga_{0.95}N layer with a thickness of 7 nm.

Well layer 105d is disposed above barrier layer 105c and functions as a well in the quantum well structure. Well layer 105d is disposed between barrier layer 105c and barrier layer 105e. In the present embodiment, well layer 105d is an undoped In_{0.18}Ga_{0.82}N layer with a thickness of 3 nm.

Barrier layer 105e is disposed above well layer 105d and functions as a barrier in the quantum well structure. In the present embodiment, barrier layer 105e is an undoped In_{0.05}Ga_{0.95}N layer with a thickness of 5 nm.

Nitride semiconductor light-emitting element 100 includes active layer 105 having a configuration as described above, and thus is capable of emitting light with a wavelength of at least 430 nm and at most 455 nm.

In the present embodiment, a band gap energy of each of barrier layers is less than or equal to the minimum value of a band gap energy of each of N-side guide layer 104 and P-side guide layer 106. In other words, the refractive index of each of the barrier layers is greater than the refractive index of each of N-side guide layer 104 and P-side guide layer 106. Accordingly, it is possible to increase the optical confinement factor indicating the degree of optical confinement into active layer 105. When each of the barrier layers includes In_{Xb}Ga_{1-Xb}N as with each of the barrier layers according to the present embodiment, the In composition ratio of each of the barrier layers is greater than or equal to the maximum value of the In composition ratio of N-side guide layer 104 and greater than or equal to the maximum value of the In composition ratio of P-side guide layer 106.

P-side guide layer 106 is an optical guide layer disposed above active layer 105. P-side guide layer 106 has a larger refractive index and a smaller band gap energy than P-type cladding layer 110. The band gap energy of P-side guide layer 106 monotonically increases with increasing distance from active layer 105.

Here, in P-side guide layer 106, a configuration in which a band gap energy monotonically increases includes a configuration in which a region where a band gap energy is constant in the stacking direction is present. In addition, P-side guide layer 106 includes a portion in which a band gap energy continuously increases with increasing distance from active layer 105. Here, a configuration in which a band gap energy continuously and monotonically increases does not include a configuration in which a band gap energy discontinuously changes in the stacking direction. According to the present disclosure, the configuration in which a band gap energy continuously and monotonically increases means a configuration in which a discontinuous increase in a band gap energy at a certain position is less than 2% of the band gap energy at the certain position, as with the above-described N-side guide layer. For example, the configuration in which the band gap energy continuously and monotonically increases does not include a configuration in which a band gap energy increases stepwise by 2% or more in the stacking direction, but includes a configuration in which a band gap energy increases stepwise by less than 2% in the stacking direction. Although a band gap energy continuously increases with increasing distance from active layer 105 in the entire P-side guide layer 106 according to the present embodiment, the configuration of P-side guide layer 106 is not limited to this configuration. For example, a proportion of the thickness of a portion of P-side guide layer 106 having a band gap energy that continuously increases with increasing distance from active layer 105 may be 50% or more of the thickness of entire P-side guide layer 106. The percentage may be 70% or more, or may be 90% or more.

Here, an amount of increase in a band gap energy of P-side guide layer 106 in the direction toward N-type second cladding layer 103 is assumed to be ΔEgp. The amount of increase in a band gap energy of P-side guide layer 106 in the stacking direction is defined by a difference between a band gap energy of P-side guide layer 106 at an interface on the side closer to active layer 105 and a band gap energy of P-side guide layer 106 at an interface on the side closer to P-type cladding layer 110. A percentage of the magnitude of a band gap energy that continuously increases may be 70% or more of ΔEgp. The percentage may be 80% or more, or may be 90% or more. As described above, by increasing the band gap energy of P-side guide layer 106 in the stacking direction, the refractive index of P-side guide layer 106 continuously and monotonically increases with decreasing distance from active layer 105. In this case, since the refractive index of P-side guide layer 106 increases with decreasing distance from active layer 105, the peak of the light intensity distribution in the stacking direction can be located closer to active layer 105. Here, if ΔEgp is small, the effect is small. Conversely, if ΔEgp is too large, the light generated from active layer 105 is absorbed in a region of P-side guide layer 106 with a small band gap energy adjacent to active layer 105, resulting in an increase in waveguide loss. In order to inhibit such waveguide loss, ΔEgp may be at least 100 meV and at most 400 meV.

When P-side guide layer 106 includes In_{Xp}Ga_{1-Xp}N, In composition ratio Xp of P-side guide layer 106 monotonically decreases with increasing distance from active layer 105. With this, the band gap energy of P-side guide layer 106 continuously and monotonically increases with increasing distance from active layer 105. In addition, P-side guide layer 106 includes a portion in which In composition ratio Xp continuously increases with increasing distance from active layer 105. Accordingly, P-side guide layer 106 includes a portion in which a band gap energy continuously increases with increasing distance from active layer 105.

As described above, an average band gap energy of P-side guide layer 106 is greater than or equal to an average band gap energy of N-side guide layer 104. In other words, an average value of the In composition ratio of P-side guide layer 106 is less than or equal to an average value of the In composition ratio of N-side guide layer 104. In the present embodiment, an average value of the In composition ratio of P-side guide layer 106 is identical to an average value of the In composition ratio of N-side guide layer 104. In addition, thickness Tp of P-side guide layer 106 is larger than thickness Tn of N-side guide layer 104. The maximum value of the In composition ratio of P-side guide layer 106 is less than or equal to the In composition ratio of each of the barrier layers.

In the present embodiment, P-side guide layer 106 is an undoped In_{Xp}Ga_{1-Xp}N layer with a thickness of 280 nm. More specifically, the composition of P-side guide layer 106 at and in the vicinity of the interface closer to active layer 105 is In_{0.04}Ga_{0.96}N, and the composition at and in the vicinity of the interface farther from active layer 105 is GaN. In composition ratio Xp of P-side guide layer 106 decreases at a constant change rate with increasing distance from active layer 105.

Intermediate layer 108 is a layer disposed above active layer 105. In the present embodiment, intermediate layer 108 is disposed between P-side guide layer 106 and electron barrier layer 109 to reduce stress caused by the difference in lattice constants between P-side guide layer 106 and electron barrier layer 109. This can inhibit the generation of crystal defects in nitride semiconductor light-emitting element 100. In the present embodiment, intermediate layer 108 is an undoped GaN layer with a thickness of 20 nm.

Electron barrier layer 109 is disposed above active layer 105 and is a nitride semiconductor layer including at least Al. In the present embodiment, electron barrier layer 109 is disposed between intermediate layer 108 and P-type cladding layer 110. Electron barrier layer 109 is a P-type Al_{0.36}Ga_{0.64}N layer with a thickness of 5 nm. Electron barrier layer 109 is doped with Mg at a concentration of 1×10¹⁹ cm⁻³ as an impurity. Electron barrier layer 109 can inhibit electrons from leaking from active layer 105 to P-type cladding layer 110.

P-type cladding layer 110 is disposed above active layer 105. In the present embodiment, P-type cladding layer 110 is disposed between electron barrier layer 109 and contact layer 111. P-type cladding layer 110 is a layer with a smaller refractive index and a larger band gap energy than active layer 105. The thickness of P-type cladding layer 110 may be 460 nm or less. This makes it possible to inhibit the electrical resistance of nitride semiconductor light-emitting element 100. This in turn makes it possible to reduce the operating voltage of nitride semiconductor light-emitting element 100. Moreover, since self-heating during operation of nitride semiconductor light-emitting element 100 can be reduced, the temperature characteristics of nitride semiconductor light-emitting element 100 can be improved. This enables high-power operation of nitride semiconductor light-emitting element 100. In order for P-type cladding layer 110 to sufficiently function as a cladding layer, in nitride semiconductor light-emitting element 100 according to the present embodiment, the thickness of P-type cladding layer 110 may be 200 nm or more. In addition, the thickness of P-type cladding layer 110 may be 250 nm or more. In the present embodiment, P-type cladding layer 110 is a P-type Al_{0.035}Ga_{0.965}N layer with a thickness of 450 nm. P-type cladding layer 110 is doped with Mg as an impurity. The impurity concentration of P-type cladding layer 110 is lower at the end portion on the side closer to active layer 105 than at the end portion on the side farther from active layer 105. More specifically, P-type cladding layer 110 includes a 150 nm thick P-type Al_{0.035}Ga_{0.965}N layer doped with Mg at a concentration of 2×10¹⁸ cm⁻³ arranged on the side closer to active layer 105, and a 300 nm thick P-type Al_{0.035}Ga_{0.965}N layer doped with Mg at a concentration of 1×10¹⁹ cm⁻³ arranged on the side farther from active layer 105.

Ridge 110R is provided in P-type cladding layer 110 of nitride semiconductor light-emitting element 100. In addition, two trenches 110T that are disposed along ridge 110R and extend in the Y-axis direction are also provided in P-type cladding layer 110. In the present embodiment, ridge width W is approximately 30 μm. As illustrated in FIG. 2A, the distance between the bottom edge of ridge 110R (i.e., the bottom of trench 110T) and active layer 105 is dp. The thickness of P-type cladding layer 110 at the bottom edge of ridge 110R (i.e., the distance between the bottom edge of ridge 110R and the interface of P-type cladding layer 110 and electron barrier layer 109) is dc.

Contact layer 111 is disposed above P-type cladding layer 110 and is in ohmic contact with P-side electrode 113. In the present embodiment, contact layer 111 is a P-type GaN layer with a thickness of 60 nm. Contact layer 111 is doped with Mg at a concentration of 1×10²⁰ cm⁻³ as an impurity.

Current blocking layer 112 is an insulating layer that is disposed above P-type cladding layer 110 and is light transmissive with respect to light from active layer 105. Current blocking layer 112 is disposed on the top surface of P-type cladding layer 110, except for the top surface of ridge 110R. In the present embodiment, current blocking layer 112 is a SiO₂ layer.

P-side electrode 113 is a conductive layer disposed above semiconductor stack 100S. In the present embodiment, P-side electrode 113 is disposed above contact layer 111 and current blocking layer 112. P-side electrode 113 is, for example, a single-layer or multilayer film formed of at least one of Ag, Cr, Ti, Ni, Pd, Pt, or Au.

P-side electrode 113 may include Ag. Ag has a significantly lower refractive index with respect to light in the UV to IR range than P-type cladding layer 110 and contact layer 111. The inclusion of Ag in P-side electrode 113 inhibits light that propagates in the waveguide between the two end faces 100F and 100R from seeping into P-side electrode 113, and thus it is possible to reduce waveguide loss generated at P-side electrode 113. Ag has a refractive index of 0.5 or less in the 325 nm to 1500 nm wavelength range, inclusive, and a refractive index of 0.2 or less in the 360 nm to 950 nm wavelength range, inclusive. Moreover, Ag has a lower rate of absorption with respect to light in the UV to IR range than other metal films such as Au. Therefore, the inclusion of Ag in P-side electrode 113 allows light loss at P-side electrode 113 to be reduced.

When P-side electrode 113 includes Ag, even when the thickness of P-type cladding layer 110 is 460 nm or less, light can be inhibited from seeping into P-side electrode 113, and thus it is possible to inhibit waveguide loss from increasing while reducing the series resistance of nitride semiconductor light-emitting element 100. As a result, it is possible to reduce the operating voltage and operating current.

When P-side electrode 113 includes Ag, the thickness of P-type cladding layer 110 may be 400 nm or less. As a result, it is possible to further reduce the operating voltage and operating current. Furthermore, even with such a thin P-type cladding layer 110, light can be confined below P-side electrode 113 and light absorption at P-side electrode 113 can be reduced, and thus it is possible to inhibit waveguide loss.

The thickness of P-type cladding layer 110 may be larger than the thickness of P-side guide layer 106 and the thickness of each of N-side guide layers 104. This allows P-type cladding layer 110 to have a thickness sufficient to confine light below P-side electrode 113, and thus it is possible to inhibit waveguide loss. When P-side electrode 113 includes Ag, for example, the thickness of P-type cladding layer 110 may be at least 200 nm and at most 400 nm. As a result, it is possible to reduce the operating voltage and operating current while inhibiting waveguide loss.

Layers with a large Al composition ratio, such as P-type cladding layer 110, have a large strain on substrate 101 which includes N-type GaN. Since the total Al content in P-type cladding layer 110 can be reduced by reducing the thickness of P-type cladding layer 110, it is possible to reduce the strain on substrate 101 by P-type cladding layer 110. Accordingly, it is possible to inhibit nitride semiconductor light-emitting element 100 from cracking due to the strain from P-type cladding layer 110.

Ag contained in P-side electrode 113 may be, for example, in ohmic contact with contact layer 111. Stated differently, P-side electrode 113 may include an Ag film in ohmic contact with contact layer 111. This allows light to be confined below contact layer 111, and thus it is possible to further reduce light loss at P-side electrode 113.

When a band gap energy of N-side guide layer 104 monotonically or continuously increases with increasing distance from active layer 105, an average refractive index of N-side guide layer 104 decreases. As a result of this, the peak position of the light intensity distribution moves in the direction from active layer 105 toward P-side guide layer 106. This in turn results in an increase in a light absorption loss at P-side electrode 113. On the other hand, the inclusion of Ag which is low in refractive index in P-side electrode 113 allows light loss at P-side electrode 113 to be reduced, and thus it is possible to inhibit waveguide loss from increasing.

N-side electrode 114 is a conductive layer disposed below substrate 101 (i.e., on the main surface of substrate 101 opposite the main surface of substrate 101 where N-type first cladding layer 102, etc. are disposed). N-side electrode 114 is, for example, a single-layer or multilayer film formed of at least one of Cr, Ti, Ni, Pd, Pt, or Au.

As a result of nitride semiconductor light-emitting element 100 having the above-described configuration, effective refractive index difference ΔN is generated between the portion below ridge 110R and the portions below trenches 110T, as illustrated in FIG. 2A. This allows the light generated in the portion of active layer 105 below ridge 110R to be confined in the horizontal direction (i.e., in the X-axis direction).

### [1-2. Light Intensity Distribution and Light Output Stability]

Next, the light intensity distribution and the light output stability of nitride semiconductor light-emitting element 100 according to the present embodiment will be described.

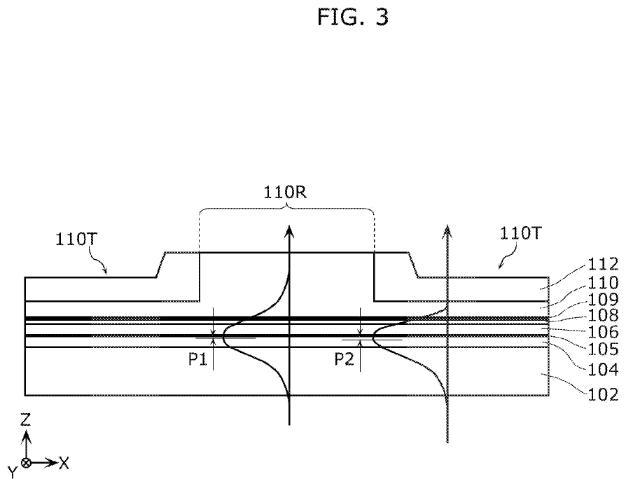

First, the light intensity distribution in the stacking direction (the Z-axis direction in the figures) of nitride semiconductor light-emitting element 100 according to the present embodiment will be described with reference to FIG. 3. FIG. 3 is a schematic diagram illustrating an outline of the light intensity distribution in the stacking direction of nitride semiconductor light-emitting element 100 according to the present embodiment. FIG. 3 includes a schematic cross-sectional view of nitride semiconductor light-emitting element 100 and a graph illustrating an outline of the light intensity distribution in the stacking direction at each of the positions corresponding to ridge 110R and trench 110T.

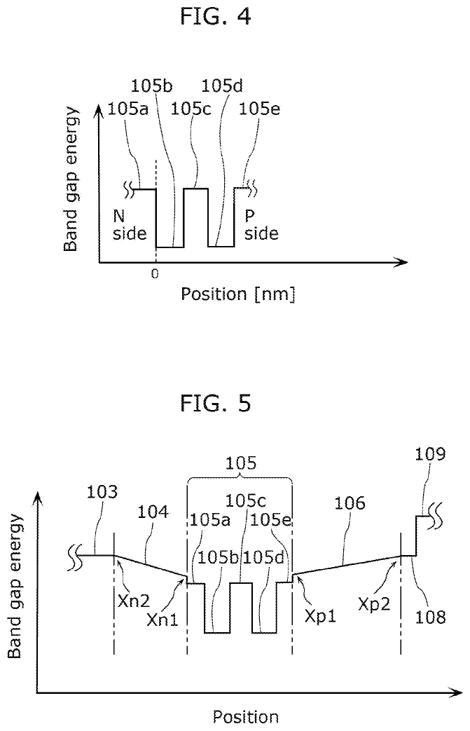

In nitride semiconductor light-emitting elements, light is generally generated in the active layer, but since the light intensity distribution in the stacking direction depends on the stacked structure, the peak of the light intensity distribution is not necessarily located in the active layer. In addition, since the stacked structure of nitride semiconductor light-emitting element 100 according to the present embodiment differs between the portion below ridge 110R and the portions below trenches 110T, the light intensity distribution also differs between the portion below ridge 110R and the portions below trenches 110T. As illustrated in FIG. 3, the peak position of the light intensity distribution in the stacking direction at the horizontal (i.e., X-axis) center of the portion below ridge 110R is P1. The peak position of the light intensity distribution in the stacking direction in the portion below trench 110T is P2. Next, positions P1 and P2 will be described with reference to FIG. 4. FIG. 4 is a graph illustrating coordinates of positions in the stacking direction of nitride semiconductor light-emitting element 100 according to the present embodiment. As illustrated in FIG. 4, the coordinates of the position in the stacking direction of the N-side end face of well layer 105b of active layer 105, i.e., the end face of well layer 105b that is closer to N-side guide layer 104, are zero, with the downward direction (toward N-side guide layer 104) being the negative direction of coordinates and the upward direction (toward P-side guide layer 106) being the positive direction of coordinates. The absolute value of the difference between positions P1 and P2 is difference ΔP of the peak position.

The following describes, with reference to FIG. 5, the light intensity distribution in the stacking direction of nitride semiconductor light-emitting element 100 according to the present embodiment. FIG. 5 is a schematic graph illustrating a band gap energy distribution in active layer 105 and layers in the vicinity thereof in nitride semiconductor light-emitting element 100 according to the present embodiment.

In nitride semiconductor light-emitting element 100 according to the present embodiment, the thickness of P-type cladding layer 110 is set relatively thin to reduce the operating voltage. Accordingly, the height of ridge 110R (i.e., the height of ridge 110R from the bottom of trench 110T) is set also relatively low. Generally, in light-emitting elements having such a configuration, the peak position of the light intensity distribution in the stacking direction shifts from active layer 105 toward N-type second cladding layer 103. This reduces the optical confinement factor into active layer 105, which in turn reduces the thermal saturation level of the light output. This makes it difficult for the semiconductor light-emitting element to perform high-output operation. As described above, in the present embodiment, the average band gap energy of P-side guide layer 106 is identical to the average band gap energy of N-side guide layer 104. Meanwhile, thickness Tp of P-side guide layer 106 is larger than thickness Tn of N-side guide layer 104 (the inequation (1) described above). As described above, by causing P-side guide layer 106 with a greater refractive index than that of each of the cladding layers to have a large thickness, it is possible to move the light intensity distribution toward P-side guide layer 106 from active layer 105. As a result, with nitride semiconductor light-emitting element 100 according to the present embodiment, it is possible to cause the peak of the light intensity distribution in the stacking direction to be located in active layer 105.

Moreover, in the present embodiment, the band gap energy of N-side guide layer 104 and the band gap energy of P-side guide layer 106 continuously and monotonically increase with increasing distance from active layer 105. In other words, the refractive indices of N-side guide layer 104 and P-side guide layer 106 continuously and monotonically increase with decreasing distance from active layer 105. In this manner, since the refractive indices of N-side guide layer 104 and P-side guide layer 106 increase with decreasing distance from active layer 105, the peak of the light intensity distribution in the stacking direction can be located closer to active layer 105.

In the present embodiment, the composition of N-side guide layer 104 and the composition of P-side guide layer 106 are represented by In_{Xn}Ga_{1-Xn}N and In_{Xp}Ga_{1-Xp}N, respectively. The composition of N-side guide layer 104 at and in the vicinity of the interface closer to active layer 105 and the composition of N-side guide layer 104 at and in the vicinity of the interface farther from active layer 105 are represented by In_{Xn1}Ga_{1-Xn1}N and In_{Xn2}Ga_{1-Xn2}N, respectively. The composition of P-side guide layer 106 at and in the vicinity of the interface closer to active layer 105 and the composition of P-side guide layer 106 at and in the vicinity of the interface farther from active layer 105 are represented by In_{Xp1}Ga_{1-Xp1}N and In_{Xp2}Ga_{1-Xp2}N, respectively. As described above, in the present embodiment, Xn1=Xp1=0.04, and Xn2=Xp2=0.

In the present embodiment, barrier layers 105a, 105c, and 105e of active layer 105 include In_{Xb}Ga_{1-Xb}N, and in regard to In composition ratios Xb, Xn, and Xp of each of the barrier layers, N-side guide layer 104, and P-side guide layer 106, Xp≤Xb (Expression 2) and Xn≤Xb (Expression 3). With this, a band gap energy of each of the barrier layers is less than or equal to the minimum value of the band gap energy of N-side guide layer 104 and the minimum value of the band gap energy of P-side guide layer 106. In other words, it is possible to cause the refractive index of each of the barrier layers to be greater than the refractive index of each of P-side guide layer 106 and N-side guide layer 104. As a result, the peak of the light intensity distribution in the stacking direction can be located closer to active layer 105. This also makes it possible to inhibit the light intensity distribution from moving too far toward P-type cladding layer 110 from active layer 105. This effect, as well as the optical confinement factor, becomes greater when a band gap energy of each of the barrier layers is less than or equal to the minimum value of the band gap energy of N-side guide layer 104 and the minimum value of the P-side guide layer 106.

With the above-described configuration, according to the present embodiment, position P1 of the peak of the light intensity distribution in the stacking direction in the portion below ridge 110R can be set to 15.9 nm. In other words, it is possible for the peak of the light intensity distribution to be located in active layer 105 (see FIG. 4). Moreover, ΔP can be inhibited to 6.2 nm. This can increase the optical confinement factor into active layer 105 to approximately 1.44%.

As described above, with nitride semiconductor light-emitting element 100 according to the present embodiment, it is possible for the peak of the light intensity distribution in the stacking direction to be located in active layer 105. It should be noted that the peak of the light intensity distribution in the stacking direction being located in active layer 105 means a state in which the peak of the light intensity distribution in the stacking direction is located in active layer 105 in at least one position in the horizontal direction of nitride semiconductor light-emitting element 100, and is not limited to a state in which the peak of the light intensity distribution in the stacking direction is located in active layer 105 at all positions in the horizontal direction.

Positioning the peak of the light intensity distribution in the stacking direction in active layer 105, as is the case in the present embodiment, can increase the proportion of the light located in P-type cladding layer 110 as compared with the case where the peak of the light intensity distribution is located in N-side guide layer 104. Here, since P-type cladding layer 110 has a higher impurity concentration than N-type first cladding layer 102 and N-type second cladding layer 103, there is concern about an increase in free carrier loss in P-type cladding layer 110 due to an increase in the proportion of light that is located in P-type cladding layer 110. However, in the present embodiment, by making P-side guide layer 106 an undoped layer, and making thickness Tp of P-side guide layer 106 relatively large, the proportion of the light intensity distribution that is located in the undoped layer can be increased. It is therefore possible to inhibit an increase in free carrier loss. More specifically, in the present embodiment, it is possible to inhibit waveguide loss to approximately 3.4 cm⁻¹.

In nitride semiconductor light-emitting element 100 according to the present embodiment, the effective refractive index difference ΔN between the portion below ridge 110R and the portions below trenches 110T is set to be relatively small in order to reduce the divergence angle of the emitted light in the horizontal direction (i.e., in the X-axis direction). More specifically, the effective refractive index difference ΔN is set by adjusting distance dp between current blocking layer 112 and active layer 105 (see FIG. 2A). Here, the larger distance dp is, the smaller effective refractive index difference ΔN is. In the present embodiment, effective refractive index difference ΔN is approximately 2.9×10⁻³. Therefore, in the present embodiment, there are fewer higher-order modes (i.e., higher-order transverse modes) that can propagate in the waveguide formed by ridge 110R as compared with the case where effective refractive index difference ΔN is larger than 2.9×10⁻³. Therefore, of all transverse modes in the emitted light of nitride semiconductor light-emitting element 100, each higher-order mode accounts for a relatively large proportion. Accordingly, the increase or decrease in the number of modes and the amount of change in the optical confinement factor into active layer 105 due to intermode coupling is relatively large. Therefore, when the number of modes increases or decreases and intermode coupling occurs in nitride semiconductor light-emitting element 100, the linearity of light output characteristics with respect to the supplied current (so-called IL characteristics) decreases. In other words, a non-linear portion (also referred to as a “kink”) occurs in the graph illustrating IL characteristics. This can result in a decrease in the stability of the light output of nitride semiconductor light-emitting element 100.

The following describes the above-described decrease in light output stability. In nitride semiconductor light-emitting element 100, the light intensity distribution in the portion below ridge 110R is dominated by the fundamental mode (i.e., the zeroth-order mode), while the light intensity distribution in the portions below trenches 110T is dominated by higher-order modes. Therefore, when difference ΔP between position P1 of the peak of the light intensity distribution in the stacking direction in the portion below ridge 110R of nitride semiconductor light-emitting element 100 and position P2 of the peak of the light intensity distribution in the stacking direction in the portion below trench 110T of nitride semiconductor light-emitting element 100 is large, the optical confinement factor into active layer 105 fluctuates as a result of occurrence of an increase or decrease in the number of modes and intermode coupling, resulting in decrease in light output stability.

For example, if the higher-order modes are reduced, the peak of the light intensity distributions in the portions below both ridge 110R and trenches 110T, when added together, moves to a position close to position P1. Accordingly, the larger difference ΔP between positions P1 and P2 is, the larger the fluctuation in the optical confinement factor into active layer 105 is when the number of modes changes. This in turn reduces the stability of light output.

In nitride semiconductor light-emitting element 100 according to the present embodiment, since N-side guide layer 104 and P-side guide layer 106 configured as described above are included, in both the portion below ridge 110R and the portions below trenches 110T, it is possible to locate the peak of the light intensity distribution in active layer 105. In other words, difference ΔP between position P1 and position P2 of the peaks of the light intensity distributions can be reduced. This inhibits fluctuations in the position in the stacking direction of the peak of the light intensity distributions in the portions below both ridge 110R and trenches 110T, when added together, even when the number of modes increases or decreases and intermode coupling occurs. It is thus possible to improve the stability of light output.

As mentioned above, distance dp is set to a relatively large value in order to set effective refractive index difference ΔN to a relatively small value. When distance dp is set so that the bottom edge of ridge 110R (i.e., the bottom of trench 110T) is below electron barrier layer 109, since electron barrier layer 109 has a large band gap energy, when holes injected from contact layer 111 pass through electron barrier layer 109, the holes can more easily leak from the sidewalls of ridge 110R to the outside of ridge 110R. As a result, holes flow downward below trenches 110T. With this, the radiative recombination probability between electrons and holes injected into active layer 105 decreases because the light intensity is small in active layer 105 below trenches 110T, and non-radiative recombination increases. The increase in non-radiative recombination as described above makes nitride semiconductor light-emitting element 100 more susceptible to degradation. In order to inhibit such degradation, the bottom edge of ridge 110R is set to be located above electron barrier layer 109. If distance dc (see FIG. 2A) from the bottom edge of ridge 110R to electron barrier layer 109 becomes too large, holes will flow from ridge 110R to between trenches 110T and electron barrier layer 109, resulting in leakage current. Distance dc is set to the smallest possible value to inhibit such an increase in leakage current. Distance dc is, for example, at least 10 nm and at most 70 nm. In the present embodiment, distance dc is 40 nm.

### 1-3. Advantageous Effects

### [1-3-1. Guide Layers]

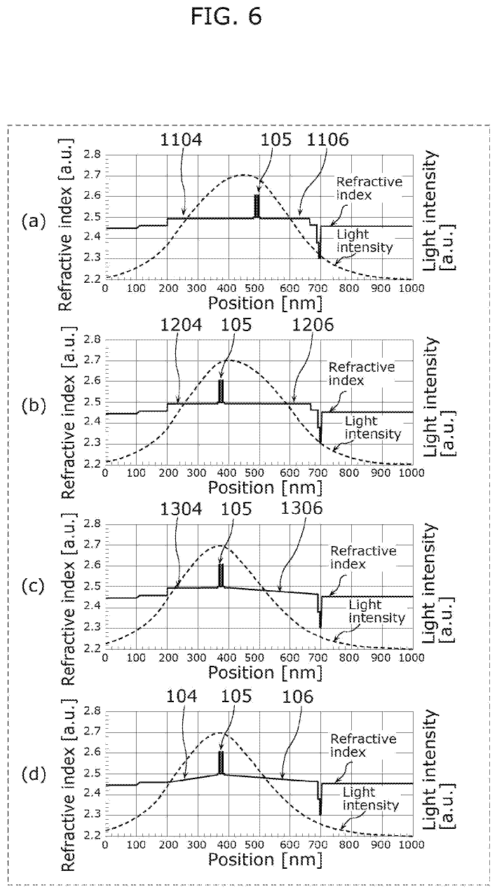

The following describes the advantageous effects of each of the guide layers of nitride semiconductor light-emitting element 100 according to the present embodiment described above, with reference to FIG. 6 through FIG. 8, in comparison with nitride semiconductor light-emitting elements according to comparative examples. FIG. 6 illustrates graphs showing the refractive index distribution and the light intensity distribution in the stacking direction of nitride semiconductor light-emitting elements according to Comparative Examples 1 through 3 and nitride semiconductor light-emitting element 100 according to the present embodiment. Graphs (a) through (c) in FIG. 6 show the refractive index distribution and the light intensity distribution of nitride semiconductor light-emitting elements according to Comparative Examples 1 through 3, respectively. Graph (d) in FIG. 6 shows the refractive index distribution and the light intensity distribution of nitride semiconductor light-emitting element 100 according to the present embodiment. In each of the graphs in FIG. 6, the refractive index distribution is indicated by a solid line, and the light intensity distribution is indicated by a dashed line.

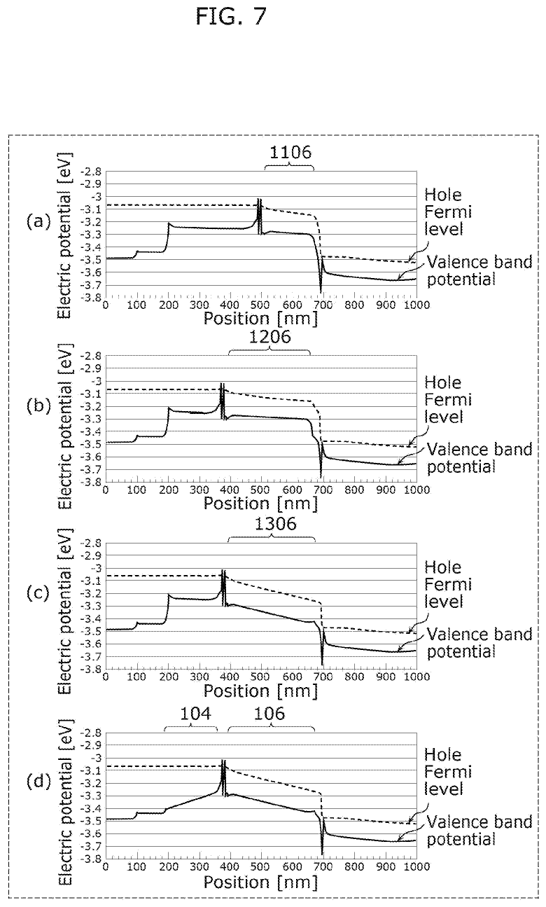

FIG. 7 illustrates graphs showing simulation results of distributions of valence band potentials and hole Fermi levels in the stacking direction of the nitride semiconductor light-emitting elements according to Comparative Examples 1 through 3 and nitride semiconductor light-emitting element 100 according to the present embodiment. Graphs (a), (b), and (c) in FIG. 7 illustrate distributions of valence band potentials and hole Fermi levels of the nitride semiconductor light-emitting elements according to Comparative Examples 1, 2, and 3, respectively. Graph (d) in FIG. 7 illustrates distributions of a valence band potential and a hole Fermi level of nitride semiconductor light-emitting element 100 according to the present embodiment. In each of the graphs in FIG. 7, the valence band potentials are indicated by a solid line, and the hole Fermi levels are indicated by a dashed line.

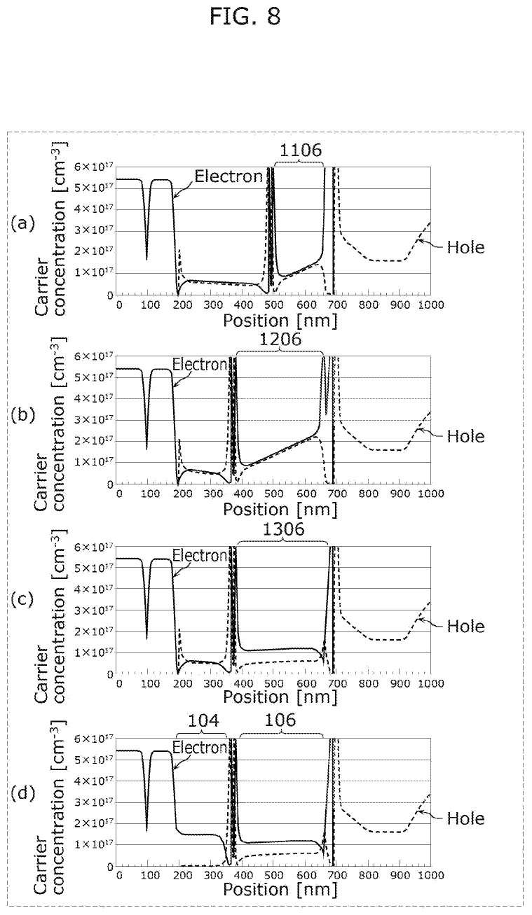

FIG. 8 illustrates graphs showing simulation results of distributions of carrier concentrations in the stacking direction of the nitride semiconductor light-emitting elements according to Comparative Examples 1 through 3 and nitride semiconductor light-emitting element 100 according to the present embodiment. Graphs (a), (b), and (c) in FIG. 8 illustrate distributions of carrier concentrations of the nitride semiconductor light-emitting elements according to Comparative Examples 1, 2, and 3, respectively. Graph (d) in FIG. 8 illustrates distributions of carrier concentrations of nitride semiconductor light-emitting element 100 according to the present embodiment. In each of the graphs in FIG. 8, the electron concentration distribution is indicated by a solid line, and the hole concentration distribution is indicated by a dashed line.

The nitride semiconductor light-emitting elements according to Comparative Examples 1 through 3 are different from nitride semiconductor light-emitting element 100 according to the present embodiment in the configurations of the N-side guide layer and the P-side guide layer. The nitride semiconductor light-emitting element according to Comparative Example 1 illustrated in graph (a) in FIG. 6 includes N-side guide layer 1104 that is an undoped In_{0.04}Ga_{0.96}N layer with a thickness of 280 nm, and P-side guide layer 1106 that is an undoped In_{0.04}Ga_{0.96}N layer with a thickness of 160 nm. The nitride semiconductor light-emitting element according to Comparative Example 2 illustrated in graph (b) in FIG. 6 includes N-side guide layer 1204 that is an undoped In_{0.04}Ga_{0.96}N layer with a thickness of 160 nm, and P-side guide layer 1206 that is an undoped In_{0.04}Ga_{0.96}N layer with a thickness of 280 nm. The nitride semiconductor light-emitting element according to Comparative Example 3 illustrated in graph (c) in FIG. 6 includes N-side guide layer 1304 that is an undoped In_{0.04}Ga_{0.96}N layer with a thickness of 160 nm, and P-side guide layer 1306 with a thickness of 280 nm. P-side guide layer 1306 of the nitride semiconductor light-emitting element according to Comparative Example 3 has the same configuration as P-side guide layer 106 according to the present embodiment.

In the nitride semiconductor light-emitting element according to Comparative Example 1, N-side guide layer 1104 and P-side guide layer 1106 have the same composition, and N-side guide layer 1104 has a thickness larger than that of P-side guide layer 1106. Accordingly, in the nitride semiconductor light-emitting element according to Comparative Example 1, a peak of the light intensity distribution in the stacking direction is located in N-side guide layer 1104, as illustrated in graph (a) in FIG. 6. As a result, the value of the optical confinement factor into the nitride semiconductor light-emitting element according to Comparative Example 1 is as low as 1.33%. As illustrated in graph (a) in FIG. 7, in P-side guide layer 1106, the hole Fermi level increases from the interface of P-side guide layer 1106 farther from active layer 105 to the interface of P-side guide layer 1106 closer to active layer 105, in order to conduct holes from P-side guide layer 1106 to active layer 105. On the other hand, the valence band potential is substantially constant in the stacking direction in P-side guide layer 1106. Accordingly, a difference between the hole Fermi level and the valence band potential in P-side guide layer 1106 increases with decreasing distance from active layer 105. As a result, as illustrated in graph (a) in FIG. 8, concentrations of holes and electrons of P-side guide layer 1106 in the stacking direction, that is, a free carrier concentration increases with increasing distance from active layer 105. As described above, in the nitride semiconductor light-emitting element according to Comparative Example 1, the free carrier concentration of P-side guide layer 1106 in the stacking direction cannot be reduced, and thus free carrier loss and the non-radiative recombination probability cannot be reduced. In the nitride semiconductor light-emitting element according to Comparative Example 1, effective refractive index difference ΔN is 3.6×10⁻³, positions P1 and P2 of the peaks of light intensity distributions are −34.1 nm and −75.6 nm, respectively, and difference ΔP is 41.5 nm. Waveguide loss is 4.5 cm⁻¹, and free carrier loss (hereinafter, also referred to as “guide-layer free carrier loss”) in each of N-side guide layer 1104 and P-side guide layer 1106 is 2.8 cm⁻¹.

In the nitride semiconductor light-emitting element according to Comparative Example 2, the thickness of P-side guide layer 1206 is larger than the thickness of N-side guide layer 1204, and thus as illustrated in graph (b) in FIG. 6, a peak of a light intensity distribution in the stacking direction is closer to active layer 105 than that in the nitride semiconductor light-emitting element according to Comparative Example 1. Accordingly, in the nitride semiconductor light-emitting element according to Comparative Example 2, the optical confinement factor is 1.37%, which is slightly improved as compared with the nitride semiconductor light-emitting element according to Comparative Example 1. However, as illustrated in graph (b) in FIG. 7, a difference between the hole Fermi level and the valence band potential in P-side guide layer 1206 increases with decreasing distance from active layer 105, in the same manner as Comparative Example 1. As a result, as illustrated in graph (b) in FIG. 8, concentrations of holes and electrons, that is, a free carrier concentration of P-side guide layer 1206 in the stacking direction increases with increasing distance from active layer 105. As described above, in the nitride semiconductor light-emitting element according to Comparative Example 2, the free carrier concentration of P-side guide layer 1206 in the stacking direction cannot be reduced, and thus free carrier loss and the non-radiative recombination probability cannot be reduced. In the nitride semiconductor light-emitting element according to Comparative Example 2, effective refractive index difference ΔN is 3.3×10⁻³, positions P1 and P2 of the peaks of light intensity distributions are 31.3 nm and 10.8 nm, respectively, and difference ΔP is 20.5 nm. In addition, waveguide loss is 5.2 cm⁻¹, and guide layer free carrier loss is 3.6 cm⁻¹.

In the nitride semiconductor light-emitting element according to Comparative Example 3, as illustrated in graph (c) in FIG. 6, since the refractive index of P-side guide layer 1306 increases with decreasing distance from active layer 105, the peak of the light intensity distribution in the stacking direction can be located closer to active layer 105. Accordingly, in nitride semiconductor light-emitting element 100 according to the present embodiment, the optical confinement factor is 1.49%, and thus is further improved as compared with the nitride semiconductor light-emitting element according to Comparative Example 2. In addition, the band gap energy of P-side guide layer 1306 continuously and monotonically increases with increasing distance from active layer 105, and thus as illustrated in graph (d) in FIG. 7, a valence band potential continuously decreases with increasing distance from active layer 105. It is thus possible to make a difference between the hole Fermi level and the valence band potential substantially constant in P-side guide layer 1306. Accordingly, as illustrated in graph (c) in FIG. 8, concentrations of holes and electrons of P-side guide layer 1306 in the stacking direction can be reduced and made substantially constant. As described above, it is possible to reduce the free carrier concentration of P-side guide layer 1306 in the stacking direction. However, a band gap energy is discontinuous at the interface of N-side guide layer 1304 farther from active layer 105 (i.e., the interface with N-type second cladding layer 103), and thus the concentration of holes increases in a spiking manner at the interface as illustrated in graph (c) in FIG. 8. Accordingly, in the nitride semiconductor light-emitting element according to Comparative Example 3, the non-radiative recombination probability and free carrier loss in N-side guide layer 1304 also cannot be reduced. In the nitride semiconductor light-emitting element according to Comparative Example 3, effective refractive index difference ΔN is 2.1×10⁻³, positions P1 and P2 of the peaks of light intensity distributions are 1.3 nm and −4.3 nm, respectively, and difference ΔP is 5.6 nm. In addition, waveguide loss is 3.20 cm⁻¹, and guide layer free carrier loss is 1.8 cm⁻¹.

In nitride semiconductor light-emitting element 100 according to the present embodiment, as illustrated in graph (d) in FIG. 6, since not only the refractive index of P-side guide layer 106 but also the refractive index of N-side guide layer 104 increases with decreasing distance from active layer 105, it is facilitated to locate the peak of the light intensity distribution in the stacking direction further closer to active layer 105. In nitride semiconductor light-emitting element 100 according to the present embodiment, the optical confinement factor is 1.44%, and thus it is possible to obtain the optical confinement factor equivalent to the optical confinement factor into the nitride semiconductor light-emitting element according to Comparative Example 3. In addition, since the band gap energy of N-side guide layer 104 continuously and monotonically increases with increasing distance from active layer 105, it is possible to reduce the discontinuousness in the band gap energy of N-side guide layer 104 at an interface on the side farther from active layer 105. As a result, as illustrated in graph (d) in FIG. 8, it is possible to significantly reduce the concentration of holes in this interface and N-side guide layer 104 as compared with that of the nitride semiconductor light-emitting element according to Comparative Example 3. As described above, since the free carrier concentration of P-side guide layer 106 and N-side guide layer 104 can be reduced, it is possible to reduce the free carrier loss and the non-radiative recombination probability in nitride semiconductor light-emitting element4 100 according to the present embodiment. In nitride semiconductor light-emitting element 100 according to the present embodiment, effective refractive index difference ΔN is 2.9×10⁻³, positions P1 and P2 of the peaks of light intensity distributions are 15.9 nm and 9.7 nm, respectively, and difference ΔP is 6.2 nm. As described above, according to the present embodiment, position P1 and difference ΔP can be reduced, and thus a nonlinear portion is not readily generated in the graph illustrating IL characteristics. In addition, waveguide loss is 3.40 cm⁻¹, and guide layer free carrier loss is 1.45 cm⁻¹. In this manner, according to the present embodiment, it is possible to reduce the waveguide loss and free carrier loss. In particular, as compared with each of the comparative examples, it is possible to reduce the free carrier loss in the present embodiment.

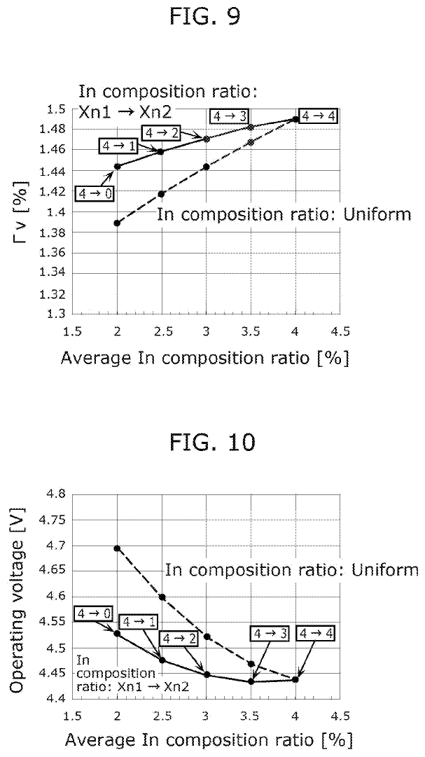

Next, the advantageous effects of the In composition ratio distribution in N-side guide layer 104 of nitride semiconductor light-emitting element 100 according to the present embodiment will be described with reference to FIG. 9 and FIG. 10. FIG. 9 and FIG. 10 illustrate graphs of simulation results of the relationship between the average In composition ratio and the optical confinement factor (Γv) and the relationship between the average In composition ratio and the operating voltage, respectively, in N-side guide layer 104 according to the present embodiment.

FIG. 9 and FIG. 10 illustrate an optical confinement factor and an operating voltage, respectively, when In composition ratio Xn1 of N-side guide layer 104 at and in the vicinity of the interface on the side closer to active layer 105 is 4%, In composition ratio Xn2 thereof at and in the vicinity of the interface on the side farther from active layer 105 is 0%, 1%, 2%, 3%, and 4%, and the In composition ratio is decreased at a certain change rate with increasing distance from active layer 105. Here, as the operating voltage, a voltage that is applied to the nitride semiconductor light-emitting element when the current supplied to the nitride semiconductor light-emitting element is 3A is indicated. FIG. 9 and FIG. 10 also illustrate simulation results when the In composition ratio of the N-side guide layer is uniform, using dashed lines.

As illustrated in FIG. 9 and FIG. 10, a high refractive index region of N-side guide layer 104 can be located closer to active layer 105 in the case where the In composition ratio of N-side guide layer 104 continuously and monotonically decreases with increasing distance from active layer 105 than in the case where the In composition ratio of N-side guide layer 104 is uniform, and thus an optical confinement factor can be increased and an operating voltage can be lowered. When the average In composition ratio is less than 2%, waveguide loss can be still more decreased, and the optical confinement factor can be still more increased.

For example, in the case where the In composition ratio of the N-side guide layer is 2% and is uniform as illustrated in FIG. 9 and FIG. 10, the optical confinement factor is 1.39%, effective refractive index difference ΔN is 3.0×10⁻³, positions P1 and P2 of the peaks of light intensity distributions are 20.4 nm and 10.4 nm, respectively, and difference ΔP is 10.0 nm. In addition, waveguide loss is 3.4 cm⁻¹, and guide layer free carrier loss is 1.38 cm⁻¹. When the In composition ratio is uniform as described above, the peak of the light intensity distribution cannot be located in the active layer, and thus the optical confinement factor is also lower than that of nitride semiconductor light-emitting element 100 according to the present embodiment.

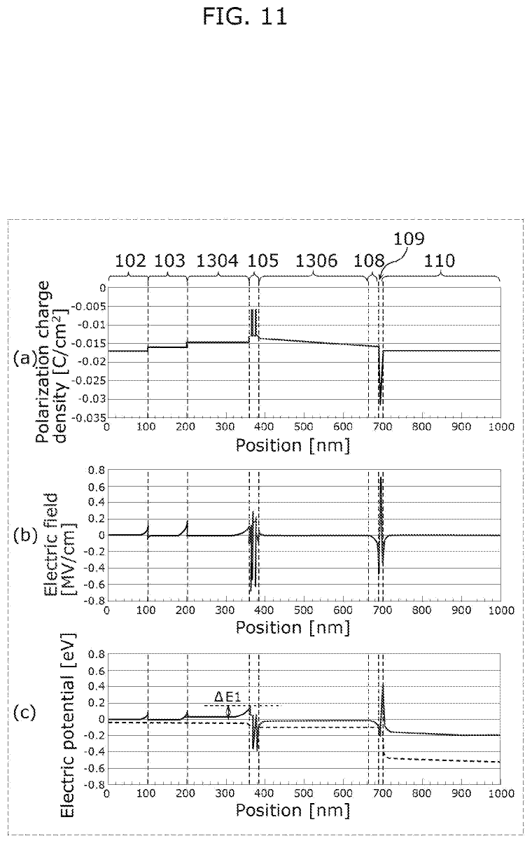

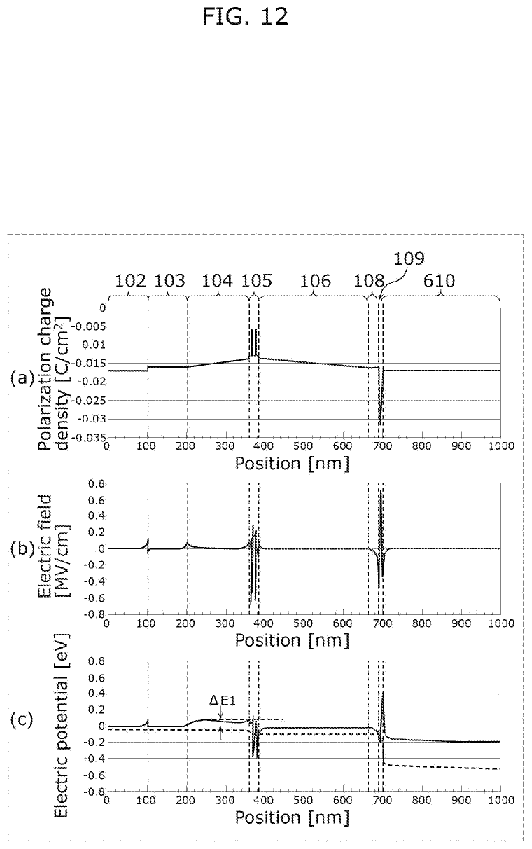

The following describes the advantageous effects of the reduction in the operating voltage of nitride semiconductor light-emitting element 100 according to the present embodiment with reference to FIG. 11 and FIG. 12, in comparison with the nitride semiconductor light-emitting element according to Comparative Example 3 described above. FIG. 11 illustrates graphs illustrating the relationships of a position in the stacking direction of the nitride semiconductor light-emitting element according to Comparative Example 3 with a piezo polarization charge density, a piezo polarization electric field, and a conduction band electric potential. FIG. 12 illustrates graphs illustrating the relationships of a position in the stacking direction of nitride semiconductor light-emitting element 100 according to the present embodiment with a piezo polarization charge density, a piezo polarization electric field, and a conduction band electric potential. Graphs (a), (b), and (c) in FIG. 11 and FIG. 12 illustrate the relationships of the position in the stacking direction of the respective nitride semiconductor light-emitting elements with the piezo polarization charge density, the piezo polarization electric field, and the conduction band electric potential. In graph (c) in each of FIG. 11 and FIG. 12, the hole Fermi levels are indicated by dashed lines.

As illustrated in graph (a) in FIG. 11, the piezo polarization charge density of N-side guide layer 1304 in the nitride semiconductor light-emitting element according to Comparative Example 3 is constant in the stacking direction. Accordingly, there are great differences in piezo polarization charge density at an interface between N-side guide layer 1304 and N-type second cladding layer 103 and an interface between N-side guide layer 1304 and active layer 105. As a result, piezo polarization charge is locally formed at an interface between N-side guide layer 1304 and N-type second cladding layer 103 and an interface between N-side guide layer 1304 and active layer 105. This in turn generates great piezo polarization electric fields. Thus, as illustrated in graph (b) in FIG. 11, a piezo polarization electric field having a spiking shape is generated at each of the interface between N-side guide layer 1304 and N-type second cladding layer 103 and the interface between N-side guide layer 1304 and active layer 105. As a result, holes are attracted to and in the vicinity of the interface between N-side guide layer 1304 and N-type second cladding layer 103 and the interface between N-side guide layer 1304 and active layer 105, and conduction band potentials at the interfaces increase (see ΔE1 illustrated in graph (c) in FIG. 11).

On the other hand, as illustrated in graph (a) in FIG. 12, the polarization charge density of N-side guide layer 104 of nitride semiconductor light-emitting element 100 according to the present embodiment monotonically decreases as approaching from the interface on the side closer to active layer 105 to the interface on the side farther from active layer 105. Accordingly, differences in piezo polarization charge density at the interface between N-side guide layer 104 and N-type second cladding layer 103 and the interface between N-side guide layer 104 and active layer 105 are reduced. Accordingly, piezo polarization charge is dispersed in the stacking direction in N-side guide layer 104. This in turn makes it possible, as illustrated in graph (b) in FIG. 12, to reduce a piezo polarization electric field at each of the interface between N-side guide layer 104 and N-type second cladding layer 103 and the interface between N-side guide layer 104 and active layer 105. As a result, as illustrated in graph (c) in FIG. 12, an increase in conduction band potential (see ΔE1 indicated in graph (c) in FIG. 12) due to holes being attracted can be inhibited at and in the vicinity of the interface between N-side guide layer 104 and N-type second cladding layer 103 and the interface between N-side guide layer 104 and active layer 105. Accordingly, in nitride semiconductor light-emitting element 100 according to the present embodiment, conductivity of electrons that flow from N-type second cladding layer 103 toward active layer 105 can be enhanced, and thus an operating voltage can be lowered.

### [1-3-2. Impurity in N-side Guide Layer]

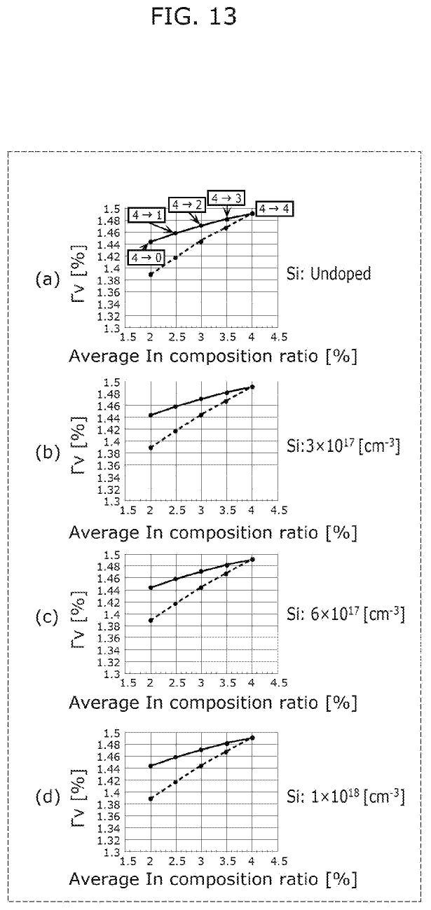

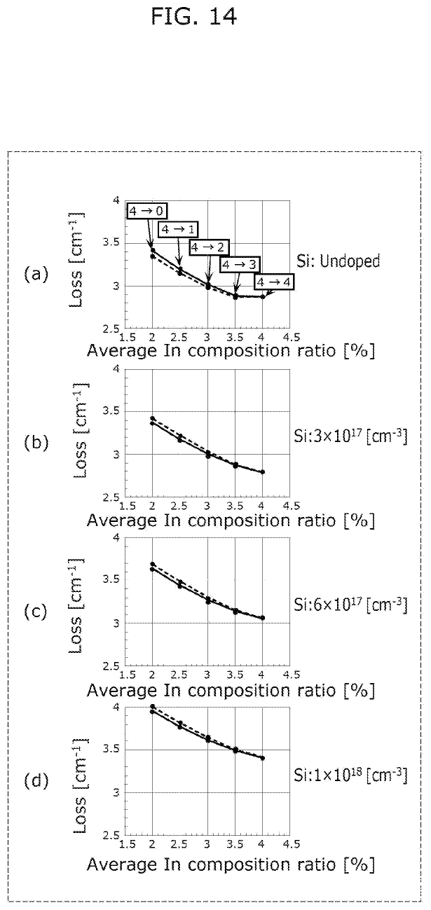

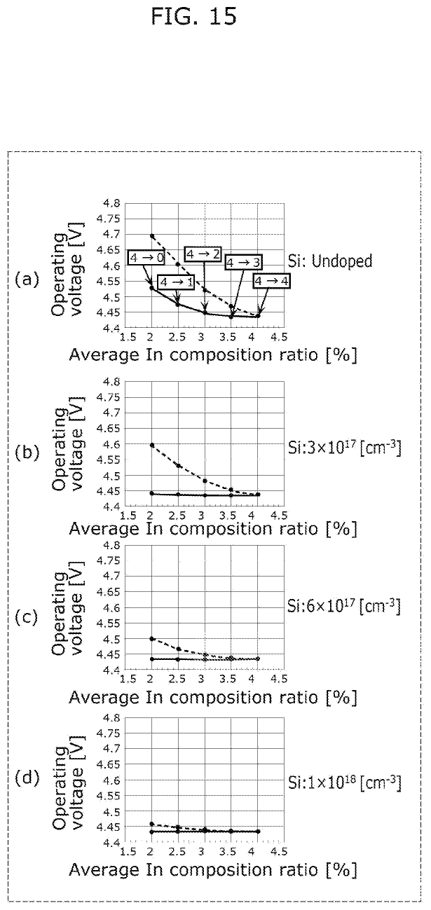

The following describes advantageous effects of an impurity in N-side guide layer 104 according to the present embodiment, with reference to FIG. 13 through FIG. 15. FIG. 13, FIG. 14, and FIG. 15 illustrate graphs of simulation results of the relationship between (i) an average In composition ratio of N-side guide layer 104 in nitride semiconductor light-emitting element 100 according to the present embodiment and (ii) an optical confinement factor (Γv), waveguide loss, and an operating voltage, respectively. Graphs (a), (b), (c), and (d) in FIG. 13 through FIG. 15 illustrate simulation results when the concentrations of an impurity (Si) in N-side guide layer 104 are 0 (that is, undoped), 3×10¹⁷ cm⁻³, 6×10¹⁷ cm⁻³, and 1×10¹⁸ cm⁻³, respectively.

FIG. 13 through FIG. 15 illustrate an optical confinement factor and an operating voltage when In composition ratio Xn1 of N-side guide layer 104 at and in the vicinity of the interface on the side closer to active layer 105 is 4%, In composition ratio Xn2 thereof at and in the vicinity of the interface on the side farther from active layer 105 is 0%, 1%, 2%, 3%, and 4%, and the In composition ratio is decreased at a certain change rate with increasing distance from active layer 105. FIG. 13 through FIG. 15. also illustrate simulation results when the In composition ratio of the N-side guide layer is uniform, using dashed lines.

As illustrated in FIG. 13, in nitride semiconductor light-emitting element 100 according to the present embodiment, an optical confinement factor can be made greater than that of the nitride semiconductor light-emitting element according to the comparative example in which the In composition ratio of the N-side guide layer is uniform. Furthermore, FIG. 13 also shows that the optical confinement factor hardly depends on an impurity concentration, in nitride semiconductor light-emitting element 100 according to the present embodiment.

As illustrated in FIG. 14, in nitride semiconductor light-emitting element 100 according to the present embodiment, waveguide loss can be reduced more than that of the nitride semiconductor light-emitting element according to the comparative example in which the In composition ratio of the N-side guide layer is uniform, except when an impurity is not added. This is considered to be caused by a decrease in hole concentration due to an energy band gap distribution in N-side guide layer 104 in the stacking direction although an electron concentration is increased by the addition of an impurity.

As illustrated in FIG. 15, in nitride semiconductor light-emitting element 100 according to the present embodiment, an operating voltage can be made lower than that of the nitride semiconductor light-emitting element according to the comparative example in which the In composition ratio of the N-side guide layer is uniform. An electron concentration in N-side guide layer 104 can be increased by increasing a concentration of an impurity added to nitride semiconductor light-emitting element 100, and thus an operating voltage can be still further lowered.

FIG. 14 and FIG. 15 show that, in nitride semiconductor light-emitting element 100 according to the present embodiment, it is possible to reduce an operating voltage while inhibiting a significant increase in waveguide loss, by setting the impurity concentration in N-side guide layer 104 to at least 1×10¹⁷ cm-3 and at most 6×10¹⁷ cm⁻³.

### [1-3-3. Thicknesses of the N-side Guide Layer and P-side Guide Layer]

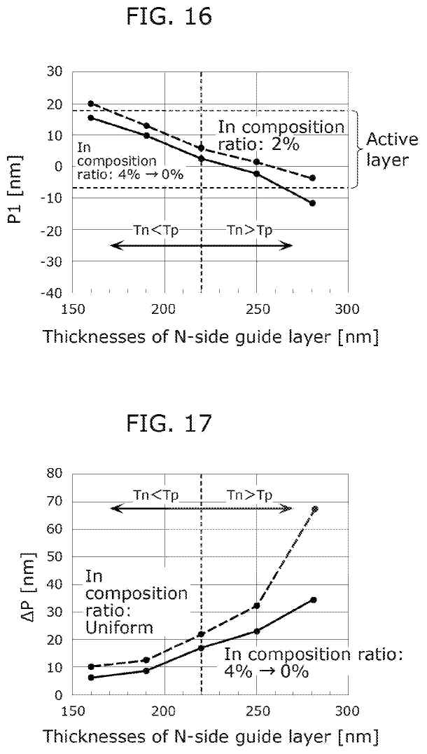

The following describes advantageous effects of a relationship between the thicknesses of N-side guide layer 104 and P-side guide layer 106 according to the present embodiment with reference to FIG. 16 and FIG. 17. FIG. 16 and FIG. 17 are graphs illustrating simulation results of the relationship between a thickness of N-side guide layer 104 and position P1, and the relationship between a thickness of N-side guide layer 104 and difference ΔP, according to the present embodiment. In the simulations as indicated by FIG. 16 and FIG. 17, the thicknesses of N-side guide layer 104 and P-side guide layer 106 are changed while a total of the thicknesses of N-side guide layer 104 and P-side guide layer 106 is maintained constant at 440 nm. The In composition ratio of each of N-side guide layer 104 and P-side guide layer 106 is 4% at and in the vicinity of the interface on the side closer to active layer 105, and is 0% at and in the vicinity of the interface on the side farther from active layer 105. The In composition ratio of each of N-side guide layer 104 and P-side guide layer 106 is changed at a constant change rate in the stacking direction. FIG. 16 and FIG. 17 also illustrate simulation results in an example in which the In composition ratio of an N-side guide layer is constant at 2% as a comparative example, using dashed lines.

As illustrated in FIG. 16, position P1 can be located in active layer 105, by setting thickness Tn of N-side guide layer 104 to at least 160 nm and at most 250 nm. In other words, the thickness of N-side guide layer 104 may be set to a value in a range from at least 36% to at most 57% of a total of the thicknesses of N-side guide layer 104 and P-side guide layer 106. In this manner, it is possible for position P1 to be at −7 nm or more and 18 nm or less; that is, for the peak of the light intensity distribution to be located in active layer 105.

As illustrated in FIG. 17, it is possible to reduce difference ΔP by setting thickness Tn of N-side guide layer 104 to a thickness less than 220 nm, or stated differently, by making thickness Tn smaller than thickness Tp of P-side guide layer 106. In particular, the thickness of N-side guide layer 104 is set to at least 23% and at most 43% of a total of the thicknesses of N-side guide layer 104 and P-side guide layer 106, thereby making difference ΔP less than or equal to 20 nm. As illustrated in FIG. 17, also when the In composition ratio of P-side guide layer 106 according to the present embodiment is constant at 2%, difference ΔP can be reduced by making the thickness of N-side guide layer 104 smaller than the thickness of P-side guide layer 106. However, difference ΔP can be further reduced by continuously and monotonically decreasing the In composition ratio with increasing distance from active layer 105, as with P-side guide layer 106 according to the present embodiment.

### [1-3-4. P-type Cladding Layer]

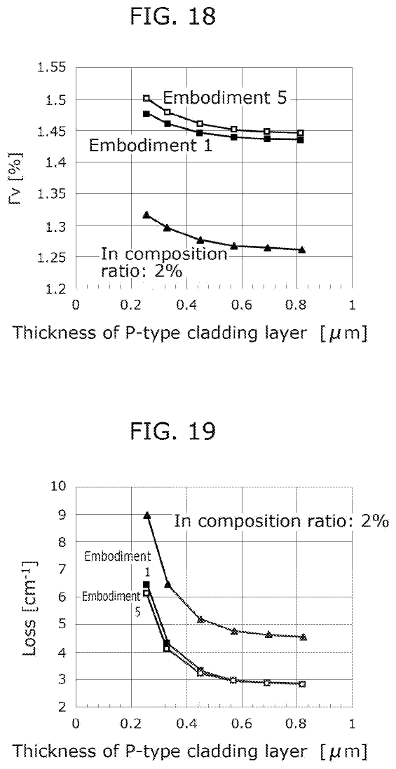

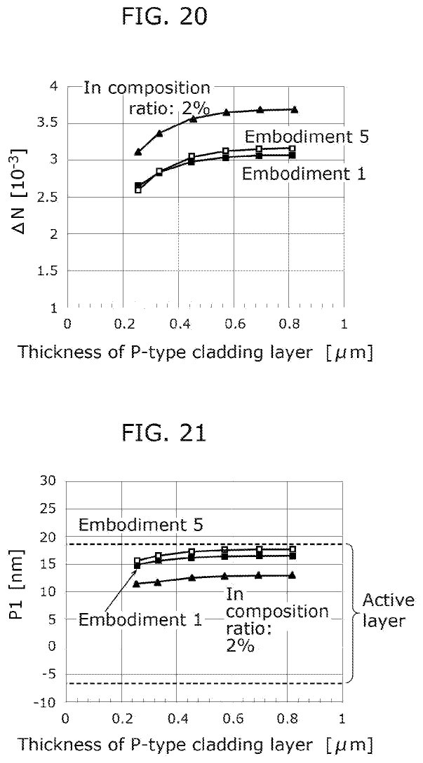

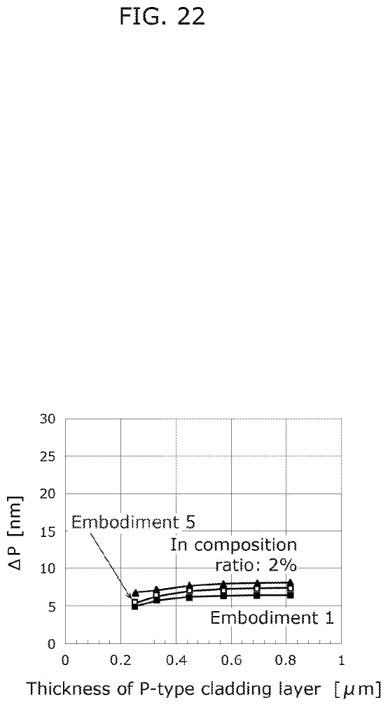

Next, the thickness of P-type cladding layer 110 according to the present embodiment will be described with reference to FIG. 18 through FIG. 22. FIG. 18 is a graph illustrating simulation results of the relationship between the thickness of P-type cladding layer 110 and an optical confinement factor (Γv) according to the present embodiment. FIG. 19 is a graph illustrating simulation results of the relationship between the thickness of P-type cladding layer 110 and waveguide loss according to the present embodiment. FIG. 20 is a graph illustrating simulation results of the relationship between the thickness of P-type cladding layer 110 and effective refractive index difference ΔN according to the present embodiment. FIG. 21 is a graph illustrating simulation results of the relationship between the thickness of P-type cladding layer 110 and position P1 according to the present embodiment. FIG. 22 is a graph illustrating simulation results of the relationship between the thickness of P-type cladding layer 110 and difference ΔP according to the present embodiment. FIG. 18 through FIG. 22 also illustrate, as comparative examples, simulation results of comparative examples in which the In composition ratio of the N-side guide layer and the In composition ratio of the P-side guide layer are both constant at 2%. FIG. 18 through FIG. 22 also illustrate simulation results of nitride semiconductor light-emitting element 300 according to Embodiment 3 described later.

As illustrated in FIG. 18, in nitride semiconductor light-emitting element 100 according to the present embodiment, an optical confinement factor can be made greater than that of the nitride semiconductor light-emitting element according to the comparative example. In the present embodiment, with the configurations of the guide layers and the barrier layers described above, the optical confinement factor does not decrease even when the thickness of P-type cladding layer 110 is made as thin as 250 nm.

As illustrated in FIG. 19, in nitride semiconductor light-emitting element 100 according to the present embodiment, waveguide loss can be made smaller than that of the nitride semiconductor light-emitting element according to the comparative example. In nitride semiconductor light-emitting element 100 according to the present embodiment, it is possible to inhibit the waveguide loss from significantly increasing even when the thickness of P-type cladding layer 110 is made as thin as approximately 300 nm.

As illustrated in FIG. 20, in nitride semiconductor light-emitting element 100 according to the present embodiment, effective refractive index difference ΔN can be made smaller than that of the nitride semiconductor light-emitting elements according to the comparative example.

As illustrated in FIG. 21, in nitride semiconductor light-emitting element 100 according to the present embodiment, position P1 can be located in active layer 105 in all of the range of 250 nm or more and 820 nm or less of the thickness of P-type cladding layer 110, as with the nitride semiconductor light-emitting element according to the comparative example. Furthermore, As illustrated in FIG. 22, in nitride semiconductor light-emitting element 100 according to the present embodiment, difference ΔP can be made smaller than that of the nitride semiconductor light-emitting element according to the comparative example, in all of the range of 250 nm or more and 820 nm or less of the thickness of P-type cladding layer 110.

As described above, the thickness of P-type cladding layer 110 can be reduced in nitride semiconductor light-emitting element 100 according to the present embodiment, and thus it is possible to reduce the operating voltage.

### [1-3-5. Barrier Layers]

Next, advantageous effects of the configurations of the barrier layers of active layer 105 according to the present embodiment will be described in comparison with a comparative example. In the present embodiment, as described above, a band gap energy of each of barrier layers is less than or equal to the minimum value of a band gap energy of N-side guide layer 104 and P-side guide layer 106. Here, as a comparative example, a simulation result of a nitride semiconductor light-emitting element according to Comparative Example 4 is shown in which the composition of the barrier layers is made undoped GaN, and thus a band gap energy of each barrier layer is made greater than the minimum value of a band gap energy of N-side guide layer 104 and P-side guide layer 106, and the other configuration is the same as that of nitride semiconductor light-emitting element 100 according to the present embodiment. In the nitride semiconductor light-emitting element according to Comparative Example 4, an optical confinement factor is 1.34%, effective refractive index difference ΔN is 3.2×10⁻³, positions P1 and P2 of the peaks of light intensity distributions are 33.9 nm and 10.3 nm, respectively, and difference ΔP is 23.6 nm In addition, waveguide loss is 3.6 cm⁻¹, and guide layer free carrier loss is 1.32 cm⁻¹. As described above, in the nitride semiconductor light-emitting element according to Comparative Example 4, a band gap energy of the barrier layers is large, or stated differently, the refractive indices of the barrier layers are small, and thus an optical confinement factor is smaller than that of nitride semiconductor light-emitting element 100 according to the present embodiment. Along with this, other evaluation indices of the nitride semiconductor light-emitting element according to Comparative Example 4 are not as good as those of nitride semiconductor light-emitting element 100 according to the present embodiment, except position P1.

As described above, in nitride semiconductor light-emitting element 100 according to the present embodiment, the optical confinement factor can be increased by setting a band gap energy of the barrier layers to a value less than or equal to the minimum value of a band gap energy of N-side guide layer 104 and P-side guide layer 106. Along with this, since difference ΔP can be reduced, a nonlinear portion is not readily generated in a graph showing IL characteristics.

### Embodiment 2

The following describes a nitride semiconductor light-emitting element according to Embodiment 2. The nitride semiconductor light-emitting element according to the present embodiment differs from nitride semiconductor light-emitting element 100 according to Embodiment 1 mainly in regard to the band gap energy distribution of a P-side guide layer. Hereinafter, the nitride semiconductor light-emitting element according to the present embodiment will be described focusing on the differences from nitride semiconductor light-emitting element 100 according to Embodiment 1.

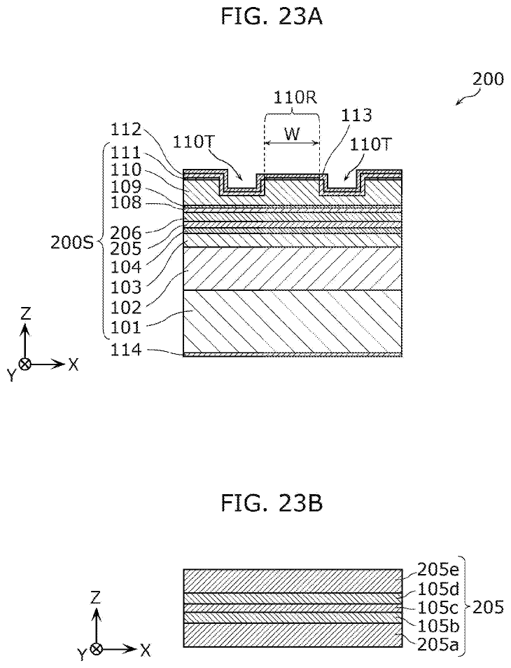

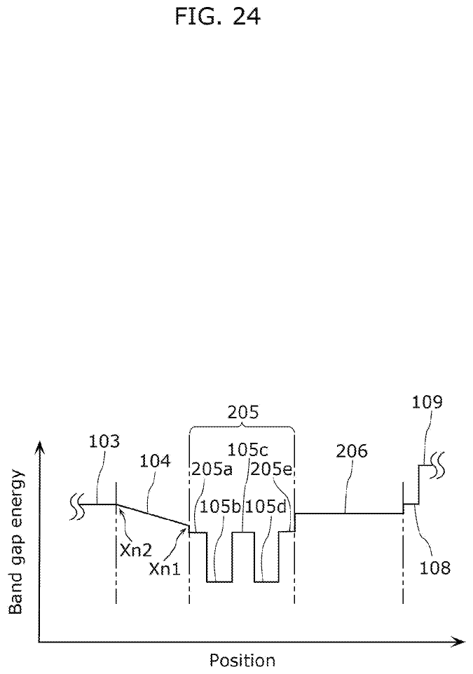

First, the overall configuration of the nitride semiconductor light-emitting element according to the present embodiment will be described with reference to FIG. 23A, FIG. 23B, and FIG. 24. FIG. 23A is a schematic cross-sectional view of the overall configuration of nitride semiconductor light-emitting element 200 according to the present embodiment. FIG. 23B is a schematic graph illustrating the configuration of active layer 205 included in nitride semiconductor light-emitting element 200 according to the present embodiment. FIG. 24 is a schematic graph illustrating a band gap energy distribution in active layer 205 and layers in the vicinity thereof in nitride semiconductor light-emitting element 200 according to the present embodiment.

As illustrated in FIG. 23A, nitride semiconductor light-emitting element 200 according to the present embodiment includes semiconductor stack 200S, current blocking layer 112, P-side electrode 113, and N-side electrode 114. Semiconductor stack 200S includes substrate 101, N-type first cladding layer 102, N-type second cladding layer 103, N-side guide layer 104, active layer 205, P-side guide layer 206, intermediate layer 108, electron barrier layer 109, P-type cladding layer 110, and contact layer 111.

Active layer 205 includes well layers 105b and 105d and barrier layers 205a, 105c, and 205e as illustrated in FIG. 23B.

Barrier layer 205a is disposed above N-side guide layer 104 and functions as a barrier in the quantum well structure. In the present embodiment, barrier layer 205a is an undoped In_{0.05}Ga_{0.95}N layer with a thickness of 6 nm.

Barrier layer 205e is disposed above well layer 105d and functions as a barrier in the quantum well structure. In the present embodiment, barrier layer 105e is an undoped In_{0.05}Ga_{0.95}N layer with a thickness of 6 nm.

P-side guide layer 206 according to the present embodiment, as illustrated in FIG. 24, differs from P-side guide layer 106 according to Embodiment 1 in that a band gap energy is constant in the stacking direction. In the present embodiment, P-side guide layer 206 is an undoped In_{Xp}Ga_{1-Xp}N layer with a thickness of 280 nm and In composition ratio Xp of 2%.

In nitride semiconductor light-emitting element 200 including such active layer 205 and P-side guide layer 206, it is also possible to reduce an operating voltage and increase an optical confinement factor into active layer 205, as with nitride semiconductor light-emitting element 100 according to Embodiment 1.

According to the present embodiment, it is possible to realize nitride semiconductor light-emitting element 200 characterized by effective refractive index difference ΔN of 3.5×10⁻³, position P1 of 11.0 nm, position P2 of 2.5 nm, difference ΔP of 8.5 nm, an optical confinement factor into active layer 205 of 1.33%, waveguide loss of 5.1 cm⁻¹, and guide layer free carrier loss of 2.6 cm⁻¹.

### Embodiment 3

The following describes a nitride semiconductor light-emitting element according to Embodiment 3. The nitride semiconductor light-emitting element according to the present embodiment differs from nitride semiconductor light-emitting element 200 according to Embodiment 2 in regard to the band gap energy distribution of a P-side guide layer. Hereinafter, the nitride semiconductor light-emitting element according to the present embodiment will be described focusing on the differences from nitride semiconductor light-emitting element 200 according to Embodiment 2.

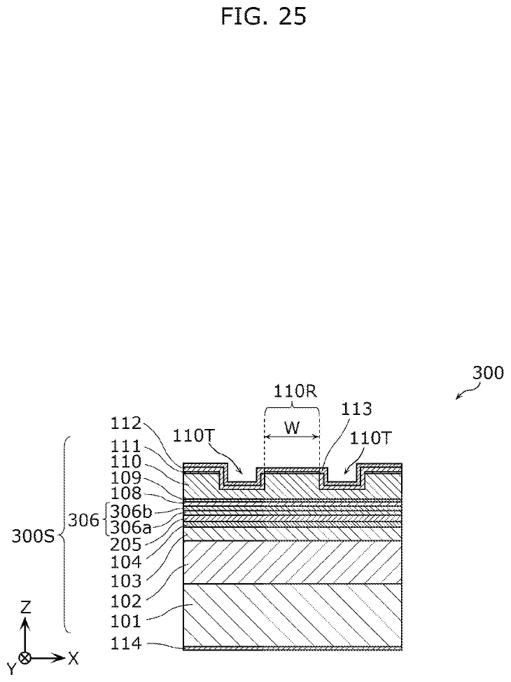

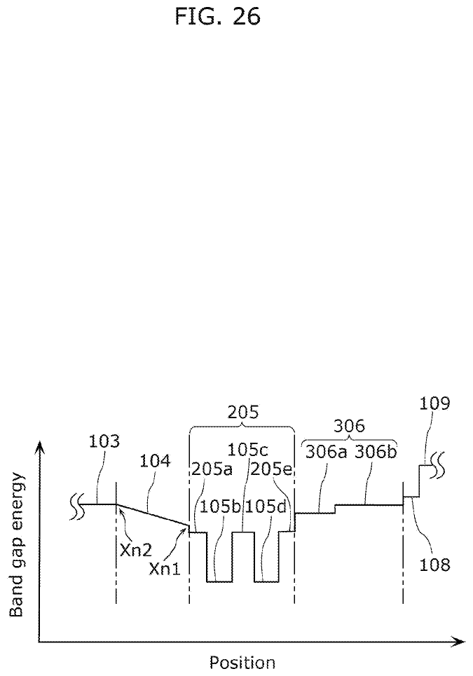

First, the overall configuration of the nitride semiconductor light-emitting element according to the present embodiment will be described with reference to FIG. 25 and FIG. 26. FIG. 25 is a schematic cross-sectional view of the overall configuration of nitride semiconductor light-emitting element 300 according to the present embodiment. FIG. 26 is a schematic graph illustrating a band gap energy distribution in active layer 205 and layers in the vicinity thereof in nitride semiconductor light-emitting element 300 according to the present embodiment.

As illustrated in FIG. 25, nitride semiconductor light-emitting element 300 according to the present embodiment includes semiconductor stack 300S, current blocking layer 112, P-side electrode 113, and N-side electrode 114. Semiconductor stack 300S includes substrate 101, N-type first cladding layer 102, N-type second cladding layer 103, N-side guide layer 104, active layer 205, P-side guide layer 306, intermediate layer 108, electron barrier layer 109, P-type cladding layer 110, and contact layer 111.

P-side guide layer 306 according to the present embodiment, as illustrated in FIG. 24, differs from P-side guide layer 206 according to Embodiment 2 in that a band gap energy changes stepwise in the stacking direction. P-side guide layer 306 includes P-side first guide layer 306a and P-side second guide layer 306b. P-side first guide layer 306a is a guide layer that is disposed above active layer 205 and has a band gap energy greater than a band gap energy of active layer 205. P-side second guide layer 306b is a guide layer that is disposed above P-side first guide layer 306a and has a band gap energy greater than a band gap energy of P-side first guide layer 306a. In the present embodiment, P-side first guide layer 306a is an undoped In_{0.04}Ga_{0.96}N layer with a thickness of 80 nm, and P-side second guide layer 306b is an undoped In_{0.01}Ga_{0.99}N layer with a thickness of 200 nm. As described above, P-side first guide layer 306a has an In composition ratio greater than that of P-side second guide layer 306b.

In nitride semiconductor light-emitting element 300 including such P-side guide layer 306, it is also possible to reduce an operating voltage and increase an optical confinement factor into active layer 205, as with nitride semiconductor light-emitting element 200 according to Embodiment 3.

According to the present embodiment, it is possible to realize nitride semiconductor light-emitting element 300 characterized by effective refractive index difference ΔN of 2.8×10−3, position P1 of 13.0 nm, position P2 of 9.1 nm, difference ΔP of 3.9 nm, an optical confinement factor into active layer 205 of 1.47%, waveguide loss of 3.9 cm⁻¹, and guide layer free carrier loss of 1.9 cm⁻¹.

The following describes the advantageous effects of nitride semiconductor light-emitting element 300 according to the present embodiment in comparison with nitride semiconductor light-emitting elements according to Comparative Example 5 through Comparative Example 7.

The nitride semiconductor light-emitting element according to Comparative Example 5 is different from nitride semiconductor light-emitting element 300 according to the present embodiment in that the N-side guide layer has a constant band gap energy in the stacking direction. The N-side guide layer included in the nitride semiconductor light-emitting element of Comparative Example 5 is an N-type In_{0.02}Ga_{0.98}N layer having a thickness of 160 nm, and is doped with Si at a concentration of 3×10¹⁷ cm⁻³ as an impurity. In the nitride semiconductor light-emitting element according to Comparative Example 5, effective refractive index difference ΔN is 3.5×10⁻³, position P1 is 12.6 nm, position P2 is 4.7 nm, difference ΔP is 7.9 nm, an optical confinement factor into active layer 205 is 1.27%, waveguide loss is 5.1 cm⁻¹, and guide layer free carrier loss is 2.5 cm⁻¹.

As described above, nitride semiconductor light-emitting element 300 according to the present embodiment includes N-side guide layer 104 having the above-described configuration, and thus it is possible to make the optical confinement factor greater than that of the nitride semiconductor light-emitting element of Comparative Example 5.

The nitride semiconductor light-emitting elements according to Comparative Example 6 and Comparative Example 7 are different from nitride semiconductor light-emitting element 300 according to the present embodiment in that the average band gap energy of the P-side guide layer is smaller than the average band gap energy of the N-side guide layer. The P-side guide layers included in the nitride semiconductor light-emitting elements according to Comparative Example 6 and Comparative Example 7 each include a P-side first guide layer that is an undoped In_{0.04}Ga_{0.96}N layer with a thickness of 100 nm, and a P-side second guide layer that is disposed above the P-side first guide layer and is an undoped In_{0.04}Ga_{0.96}N layer with a thickness of 100 nm. The N-side guide layer included in the nitride semiconductor light-emitting element according to Comparative Example 6 has the same configuration as that of N-side guide layer 104 according to the present embodiment. The N-side guide layer included in the nitride semiconductor light-emitting element according to Comparative Example 7 has a band gap energy that is constant in the stacking direction. More specifically, the N-side guide layer included in the nitride semiconductor light-emitting element of Comparative Example 7 is an N-type In_{0.04}Ga_{0.96}N layer having a thickness of 160 nm, and is doped with Si at a concentration of 3×10¹⁷ cm⁻³ as an impurity.

In the nitride semiconductor light-emitting elements of Comparative Example 6 and Comparative Example 7, position P1 is 32.7 nm and 38.3 nm, respectively, and the peak position of the light intensity distribution is located outside of the active layer and in the P-side guide layer. Therefore, when coupling occurs between the higher-order mode that can propagate in the waveguide formed by ridge 110R and the lower-order mode that are stably confined in the waveguide, the optical confinement factor are likely to change. In other words, the linearity of IL characteristics is likely to decrease. In particular, when effective refractive index difference ΔN is as small as 3.0×10³ as in Comparative Example 6 and Comparative Example 7, the total number of higher-order modes that can propagate in the waveguide is reduced, and thus the effect on the IL characteristics caused by intermode coupling increases. For this reason, the linearity of the IL characteristics of the nitride semiconductor light-emitting element according to Comparative Example 6 and Comparative Example 7 is likely to decrease.

On the other hand, in nitride semiconductor light-emitting element 300 according to the present embodiment, position P1 is 13.0 nm, which is significantly smaller than position P1 of the nitride semiconductor light-emitting elements according to Comparative Example 6 and Comparative Example 7. Accordingly, it is possible to inhibit a decrease in the linearity of the IL characteristics.

### Embodiment 4

The following describes a nitride semiconductor light-emitting element according to Embodiment 4. The nitride semiconductor light-emitting element according to the present embodiment differs from nitride semiconductor light-emitting element 100 according to Embodiment 1 mainly in regard to the band gap energy distribution of a N-side guide layer. Hereinafter, the nitride semiconductor light-emitting element according to the present embodiment will be described focusing on the differences from nitride semiconductor light-emitting element 100 according to Embodiment 1.

### 4-1. Overall Configuration

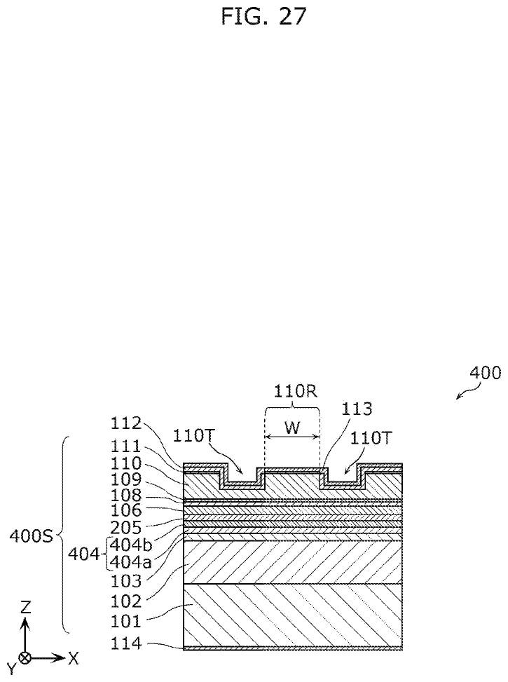

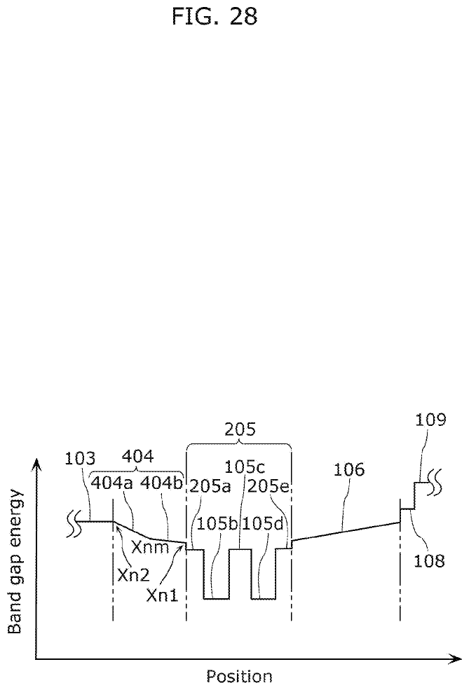

First, the overall configuration of the nitride semiconductor light-emitting element according to the present embodiment will be described with reference to FIG. 27 and FIG. 28. FIG. 27 is a schematic cross-sectional view of the overall configuration of nitride semiconductor light-emitting element 400 according to the present embodiment. FIG. 28 is a schematic graph illustrating a band gap energy distribution in active layer 205 and layers in the vicinity thereof in nitride semiconductor light-emitting element 400 according to the present embodiment.

As illustrated in FIG. 27, nitride semiconductor light-emitting element 400 according to the present embodiment includes semiconductor stack 400S, current blocking layer 112, P-side electrode 113, and N-side electrode 114. Semiconductor stack 400S includes substrate 101, N-type first cladding layer 102, N-type second cladding layer 103, N-side guide layer 404, active layer 205, P-side guide layer 106, intermediate layer 108, electron barrier layer 109, P-type cladding layer 110, and contact layer 111.

In N-side guide layer 404 according to the present embodiment, the band gap energy continuously and monotonically increases with increasing distance from active layer 205, as with N-side guide layer 104 according to Embodiment 1. According to the present embodiment, N-side guide layer 404 is an N-type In_{Xn}Ga_{1-Xn}N layer and is doped with Si at a concentration of 3×10¹⁷ cm⁻³ as an impurity. The absolute value of the average change rate of the In composition ratio in the stacking direction in the region from the interface on the side closer to active layer 205 of N-side guide layer 404 to the central portion of N-side guide layer 404 in the stacking direction is smaller than the absolute value of the average change rate of the In composition ratio in the stacking direction in the region from the central portion to the interface on the side closer to N-type first cladding layer 102 of N-side guide layer 404. In other words, a curve indicating the relationship between a position in the stacking direction and the In composition ratio of N-side guide layer 404 has an upward convex shape. Stated differently, a curve indicating the relationship between a position in the stacking direction and a band gap energy of N-side guide layer 404 has a downward convex shape (see FIG. 28).

N-side guide layer 404 includes N-side first guide layer 404a and N-side second guide layer 404b. N-side first guide layer 404a is a guide layer disposed above N-type second cladding layer 103. N-side first guide layer 404a is an In_{Xn}Ga_{1-Xn}N layer with a thickness of 80 nm. More specifically, the composition of N-side first guide layer 404a at an interface on the side farther from active layer 205 is In_{Xn}2Ga_{1-Xn2}N, and the composition at and in the vicinity of the interface closer to active layer 205 is In_{Xnm}Ga_{1-Xnm}N (see FIG. 28). In composition ratio Xn of N-side first guide layer 404a decreases at a constant change rate with increasing distance from active layer 105. N-side second guide layer 404b is a guide layer disposed above N-side first guide layer 404a. In other words, N-side second guide layer 404b is disposed between N-side first guide layer 404a and active layer 205. N-side second guide layer 404b is an In_{Xn}Ga_{1-Xn}N layer with a thickness of 80 nm. More specifically, the composition of N-side second guide layer 404b at an interface on the side closer to active layer 205 is In_{Xn1}Ga_{1-Xn1}N, and the composition at and in the vicinity of the interface farther from active layer 205 is In_{Xnm}Ga_{1-Xnm}N. In composition ratio Xn of N-side second guide layer 404b decreases at a constant change rate with increasing distance from active layer 105. In the present embodiment, Xn1=0.04, Xnm=0.03, and Xn2=0.

### 4-2. Advantageous Effects

### [4-2-1. In Composition Ratio Distribution]

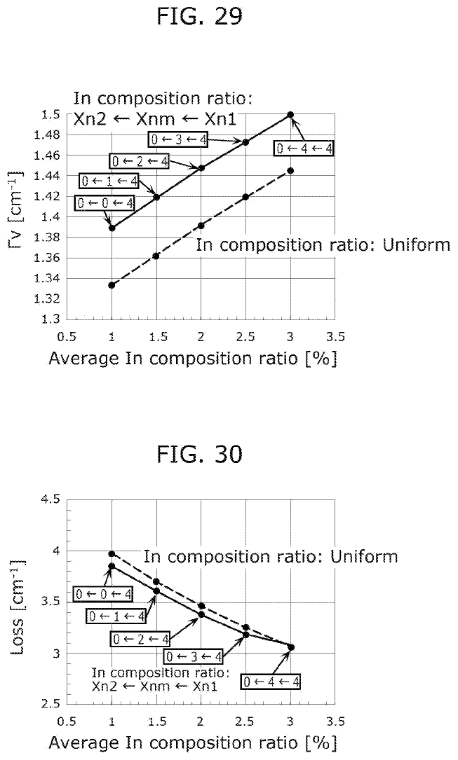

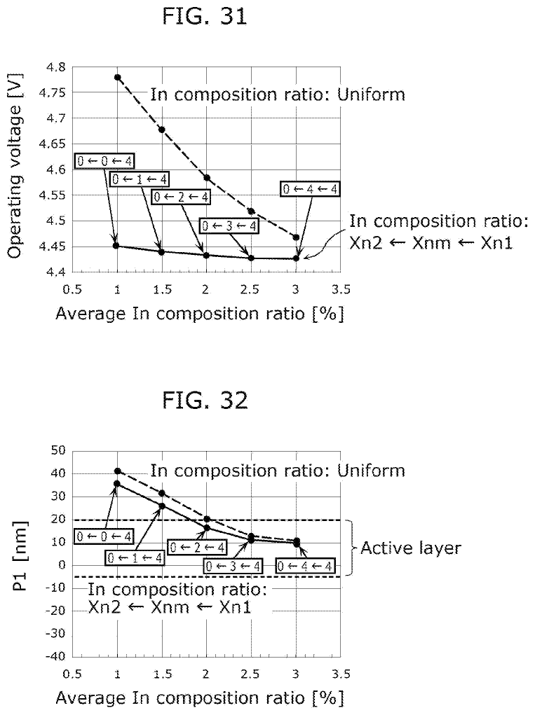

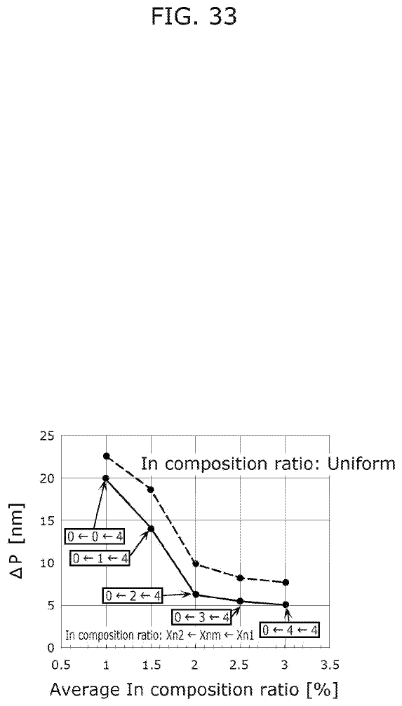

Next, the advantageous effects of the In composition ratio distribution in N-side guide layer 404 of nitride semiconductor light-emitting element 400 according to the present embodiment will be described with reference to FIG. 29 through FIG. 33. FIG. 29 is a graph illustrating simulation results of the relationship between an average In composition ratio of N-side guide layer 404 and an optical confinement factor (Γv) according to the present embodiment. FIG. 30 is a graph illustrating simulation results of the relationship between an average In composition ratio of N-side guide layer 404 and waveguide loss according to the present embodiment. FIG. 31 is a graph illustrating simulation results of the relationship between an average In composition ratio of N-side guide layer 404 and an operating voltage according to the present embodiment. FIG. 32 and FIG. 33 are graphs illustrating simulation results of the relationship between an average In composition ratio of N-side guide layer 404 and position P1, and the relationship between an average In composition ratio of N-side guide layer 404 and difference ΔP, respectively, according to the present embodiment. FIG. 29 through FIG. 33 illustrate the waveguide loss and optical confinement factors of N-side guide layer 404 when: In composition ratio Xp1 at and in the vicinity of the interface on the side closer to active layer 205 is 4%; In composition ratio Xp2 at and in the vicinity of the interface on the side farther from active layer 205 is 0%; and the In composition ratio is continuously and monotonically decreased with increasing distance from active layer 205. More specifically, FIG. 29 through FIG. 33 illustrate simulate results of the case where an average In composition ratio in N-side guide layer 404 is changed by changing In composition ratio Xnm in the central portion of N-side guide layer 404 in the stacking direction. FIG. 29 through FIG. 33 also illustrate simulation results when the In composition ratio of the N-side guide layer is uniform, using dashed lines.

In the examples illustrated in FIG. 29 through FIG. 33, when the average In composition ratio is greater than 2%, a curve indicating the relationship between a position in the stacking direction and the In composition ratio of N-side guide layer 404 has a convex shape. For example, the case where the average In composition ratio is 2.5% corresponds to nitride semiconductor light-emitting element 400 according to the present embodiment.

As illustrated in FIG. 29 and FIG. 30, the optical confinement factor can be more increased and waveguide loss can be more decreased in the case where the In composition ratio in N-side guide layer 404 continuously and monotonically decreases with increasing distance from active layer 205 than in the case where the In composition ratio in the N-side guide layer is uniform. When the average In composition ratio is greater than 2%, the optical confinement factor can be still more increased and waveguide loss can be still more decreased.

As illustrated in FIG. 31, the operating voltage can be more decreased in the case where the In composition ratio in N-side guide layer 404 continuously and monotonically decreases with increasing distance from active layer 205 than in the case where the In composition ratio in the N-side guide layer is uniform. Furthermore, the operating voltage can be still more decreased in the case where the average In composition ratio is greater than 2%.

As illustrated in FIG. 32 and FIG. 33, position P1 of the peak of a light intensity distribution can further be located closer to active layer 205 and difference ΔP can further be reduced in the case where the In composition ratio in N-side guide layer 404 continuously and monotonically decreases with increasing distance from active layer 205 than in the case where the In composition ratio in the N-side guide layer is uniform. In addition, when the average In composition ratio is greater than 2%, position P1 can be located within active layer 205 and difference ΔP can be still more decreased. This is considered to be due to the fact that when an average In composition ratio is greater than 2%, the refractive index of the region of N-side guide layer 404 that is closer to active layer 205 can be more increased, and thus light can be guided to the vicinity of active layer 205.

### [4-2-2. Barrier Layers]

Next, advantageous effects of the configurations of the barrier layers of active layer 205 according to the present embodiment will be described in comparison with a comparative example. In the present embodiment, as described above, a band gap energy of each of barrier layers is less than or equal to the minimum value of a band gap energy of N-side guide layer 404 and P-side guide layer 106. Here, as a comparative example, a simulation result of a nitride semiconductor light-emitting element according to Comparative Example 8 is shown in which the composition of the barrier layers is made undoped GaN, and thus a band gap energy of each barrier layer is made greater than the minimum value of a band gap energy of N-side guide layer 404 and P-side guide layer 106, and the other configuration is the same as that of nitride semiconductor light-emitting element 400 according to the present embodiment. In the nitride semiconductor light-emitting element according to Comparative Example 8, an optical confinement factor is 1.36%, effective refractive index difference ΔN is 3.4×10⁻³, positions P1 and P2 of the peaks of light intensity distributions are 22.8 nm and 2.2 nm, respectively, and difference ΔP is 20.6 nm In addition, waveguide loss is 3.4 cm⁻¹, and free carrier loss in the N-side guide layer and the P-side guide layer is 1.4 cm⁻¹.

In contrast, according to the present embodiment, an optical confinement factor is 1.44%, effective refractive index difference ΔN is 3.4×10⁻³, positions P1 and P2 of the peaks of light intensity distributions are 10.9 nm and 5.5 nm, respectively, and difference ΔP is 5.4 nm In addition, waveguide loss is 3.4 cm⁻¹, and guide layer free carrier loss is 1.7 cm⁻¹.

As described above, in the present embodiment, the band gap energy of each barrier layer is less than or equal to that of each guide layer, that is, the refractive index of each barrier layer is greater than that of each guide layer, and thus the optical confinement factor can further be increased compared to the nitride semiconductor light-emitting element in Comparative Example 8. Accordingly, in the present embodiment, position P1 and difference ΔP also can further be decreased compared to the nitride semiconductor light-emitting element in Comparative Example 8. As described above, according to the present embodiment, difference ΔP can be reduced, and thus a nonlinear portion is not readily generated in the graph illustrating IL characteristics.

### Embodiment 5

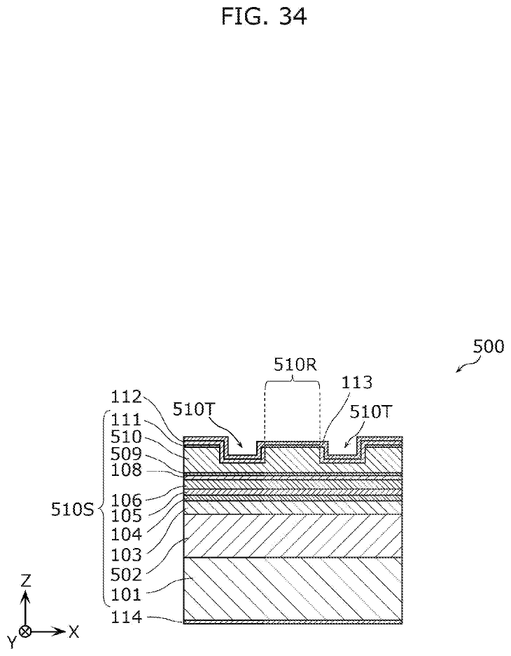

The following describes a nitride semiconductor light-emitting element according to Embodiment 5. The nitride semiconductor light-emitting element according to the present embodiment differs from nitride semiconductor light-emitting element 100 according to Embodiment 1 in regard to the relationship between the Al composition ratios of the N-type first cladding layer and the P-type cladding layer, and the configuration of an electron barrier layer. Hereinafter, the nitride semiconductor light-emitting element according to the present embodiment will be described with reference to FIG. 34, focusing on the differences from nitride semiconductor light-emitting element 100 according to Embodiment 1.

FIG. 34 is a schematic cross-sectional view of the overall configuration of nitride semiconductor light-emitting element 500 according to the present embodiment.

As illustrated in FIG. 34, nitride semiconductor light-emitting element 500 according to the present embodiment includes semiconductor stack 500S, current blocking layer 112, P-side electrode 113, and N-side electrode 114. Semiconductor stack 500S includes substrate 101, N-type first cladding layer 502, N-type second cladding layer 103, N-side guide layer 104, active layer 105, P-side guide layer 106, intermediate layer 108, electron barrier layer 509, P-type cladding layer 510, and contact layer 111.

N-type first cladding layer 502 according to the present embodiment is an N-type Al_{0.036}Ga_{0.964}N layer with a thickness of 1200 nm. N-type first cladding layer 502 is doped with Si at a concentration of 1×10¹⁸ cm³ as an impurity.

P-type cladding layer 510 according to the present embodiment is disposed between electron barrier layer 509 and contact layer 111. P-type cladding layer 510 is a layer with a smaller refractive index and a larger band gap energy than those of active layer 105. In the present embodiment, P-type cladding layer 510 is a P-type Al_{0.026}Ga_{0.974}N layer with a thickness of 450 nm. P-type cladding layer 510 is doped with Mg as an impurity. The impurity concentration of P-type cladding layer 510 is lower at the end portion on the side closer to active layer 105 than at the end on the side portion farther from active layer 105. More specifically, P-type cladding layer 510 includes a 150 nm thick P-type Al_{0.026}Ga_{0.974}N layer doped with Mg at a concentration of 2×10¹⁸ cm⁻³ arranged on the side closer to active layer 105, and a 300 nm thick P-type Al_{0.026}Ga_{0.974}N layer doped with Mg at a concentration of 1×10¹⁹ cm⁻³ arranged on the side farther from active layer 105.

Ridge 510R is formed in P-type cladding layer 510 as with nitride semiconductor light-emitting element 100 according to Embodiment 1. Two trenches 510T disposed along ridge 510R and extending in the Y-axis direction are also formed in P-type cladding layer 510.

In the present embodiment, N-type first cladding layer 502 and P-type cladding layer 510 include Al, and Ync>Ypc (Expression 4), where Ync is the Al composition ratio of N-type first cladding layer 502 and Ypc is the Al composition ratio of P-type cladding layer 510.

If at least one of N-type first cladding layer 502 or P-type cladding layer 510 has a superlattice structure, composition ratios Ync and Ypc indicate the average Al composition ratio. For example, if N-type first cladding layer 502 includes a plurality of 2 nm thick GaN layers and a plurality of 2 nm thick AlGaN layers with an Al composition ratio of 0.07, and the plurality of GaN layers and the plurality of AlGaN layers are alternately stacked, Ync is the average Al composition ratio across the entirety of N-type first cladding layer 502, which is 0.035. When P-type cladding layer 510 includes a plurality of 2 nm thick GaN layers and a plurality of 2 nm thick AlGaN layers with an Al composition ratio of 0.07, and the plurality of GaN layers and the plurality of AlGaN layers are alternately stacked, Ypc is the average Al composition ratio across the entirety of P-type cladding layer 510, which is 0.035.

The above-described Expression 4 is satisfied, thereby allowing the refractive index of N-type first cladding layer 502 to be reduced below the refractive index of P-type cladding layer 510. Therefore, even when the thickness of P-type cladding layer 510 is reduced in order to reduce the operating voltage of nitride semiconductor light-emitting element 500, the refractive index of N-type first cladding layer 502 is smaller than the refractive index of P-type cladding layer 510, and thus the peak of the light intensity distribution in the stacking direction can be inhibited from moving toward N-type first cladding layer 502 from active layer 105.

Electron barrier layer 509 is disposed above active layer 105 and is a nitride semiconductor layer including at least Al. In the present embodiment, electron barrier layer 509 is disposed between intermediate layer 108 and P-type cladding layer 510. Electron barrier layer 509 is a P-type AlGaN layer with a thickness of 5 nm. Electron barrier layer 509 includes an Al composition ratio gradient region where the Al composition ratio monotonically increases with decreasing distance from P-type cladding layer 510. Here, the configuration in which the Al composition ratio monotonically increases includes a configuration including a region in which the Al composition ratio is constant in the stacking direction. For example, the configuration in which the Al composition ratio monotonically increases includes a configuration in which the Al composition ratio increases stepwise. In electron barrier layer 509 according to the present embodiment, the entire electron barrier layer 509 is an Al composition ratio increasing region where the Al composition ratio increases at a constant change rate in the stacking direction. More specifically, the composition of electron barrier layer 509 at and in the vicinity of the interface with intermediate layer 108 is Al_{0.02}Ga_{0.98}N, and the Al composition ratio increases monotonically with decreasing distance from P-type cladding layer 510 such that the composition at and in the vicinity of the interface with P-type cladding layer 510 is Al_{0.36}Ga_{0.64}N. Electron barrier layer 509 is doped with Mg at a concentration of 1×10¹⁹ cm⁻³ as an impurity.

Electron barrier layer 509 can inhibit electrons from leaking from active layer 105 to P-type cladding layer 510. Moreover, by electron barrier layer 509 including an Al composition variation region in which the Al composition ratio monotonically increases, the electric potential barrier in the valence band of electron barrier layer 509 can further be reduced compared to the case where the Al composition ratio is uniform. Accordingly, holes can easily flow from P-type cladding layer 510 to active layer 105. Therefore, even when the thickness of P-side guide layer 106 which is an undoped layer is large as is the case in the present embodiment, it is possible to inhibit an increase in the electrical resistance of nitride semiconductor light-emitting element 500. This makes it possible to reduce the operating voltage of nitride semiconductor light-emitting element 500. Moreover, since self-heating during operation of nitride semiconductor light-emitting element 500 can be reduced, the temperature characteristics of nitride semiconductor light-emitting element 500 can be improved. This enables high-power operation of nitride semiconductor light-emitting element 500.

According to the present embodiment, it is possible to realize nitride semiconductor light-emitting element 500 characterized by effective refractive index difference ΔN of 3.0×10⁻³, position P1 of 17.3 nm, difference ΔP of 7.0 nm, an optical confinement factor into active layer 105 of 1.45%, waveguide loss of 3.3 cm⁻¹, and guide layer free carrier loss of 1.3 cm⁻¹.

### Embodiment 6

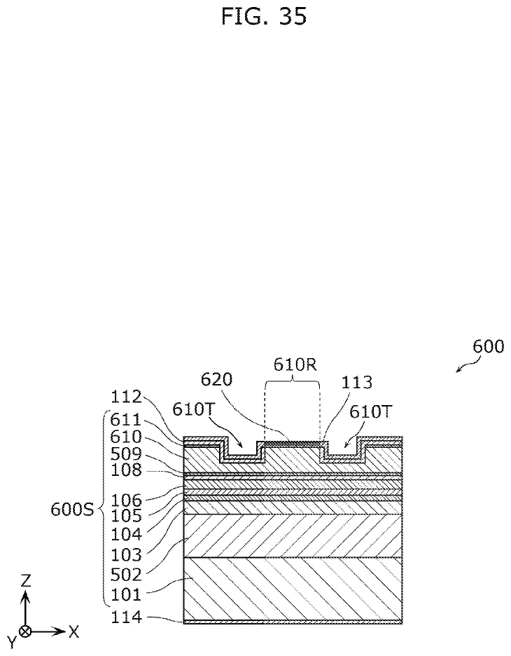

The following describes a nitride semiconductor light-emitting element according to Embodiment 6. The nitride semiconductor light-emitting element according to the present embodiment differs from nitride semiconductor light-emitting element 500 according to Embodiment 5 mainly in that it includes a light-transmissive conductive film on a contact layer of a ridge. Hereinafter, the nitride semiconductor light-emitting element according to the present embodiment will be described with reference to FIG. 35, focusing on the differences from nitride semiconductor light-emitting element 500 according to Embodiment 5.

FIG. 35 is a schematic cross-sectional view of the overall configuration of nitride semiconductor light-emitting element 600 according to the present embodiment. As illustrated in FIG. 35, nitride semiconductor light-emitting element 600 according to the present embodiment includes semiconductor stack 600S, current blocking layer 112, P-side electrode 113, N-side electrode 114, and light-transmissive conductive film 620. Semiconductor stack 600S includes substrate 101, N-type first cladding layer 502, N-type second cladding layer 103, N-side guide layer 104, active layer 105, P-side guide layer 106, intermediate layer 108, electron barrier layer 509, P-type cladding layer 610, and contact layer 611.

P-type cladding layer 610 according to the present embodiment is disposed between electron barrier layer 509 and contact layer 611. P-type cladding layer 610 is a layer with a smaller refractive index and a larger band gap energy than those of active layer 105. In the present embodiment, P-type cladding layer 610 is a P-type Al_{0.026}Ga_{0.974}N layer with a thickness of 330 nm. P-type cladding layer 610 is doped with Mg as an impurity. The impurity concentration of P-type cladding layer 610 is lower at the end portion on the side closer to active layer 105 than at the end portion on the side farther from active layer 105. More specifically, P-type cladding layer 610 includes a 150 nm thick P-type Al_{0.026}Ga_{0.974}N layer doped with Mg at a concentration of 2×10¹⁸ cm⁻³ arranged on the side closer to active layer 105, and a 180 nm thick P-type Al_{0.026}Ga_{0.974}N layer doped with Mg at a concentration of 1×10¹⁹ cm⁻³ arranged on the side farther from active layer 105.

Ridge 610R is formed in P-type cladding layer 610 as with nitride semiconductor light-emitting element 500 according to Embodiment 5. Two trenches 610T disposed along ridge 610R and extending in the Y-axis direction are also formed in P-type cladding layer 610.

Contact layer 611 is disposed above P-type cladding layer 610 and is in ohmic contact with P-side electrode 113. In the present embodiment, contact layer 611 is a P-type GaN layer with a thickness of 10 nm. Contact layer 611 is doped with Mg at a concentration of 1×10²⁰ cm⁻³ as an impurity.

Light-transmissive conductive film 620 according to the present embodiment is a conductive film that is disposed above P-type cladding layer 610 and transmits at least a portion of the light generated by nitride semiconductor light-emitting element 600. For example, an oxide film that is light-transmissive to visible light and exhibits low-resistance electrical conductivity, such as tin-doped indium oxide (ITO), Ga-doped zinc oxide, Al-doped zinc oxide, and In- and Ga-doped zinc oxide can be used as light-transmissive conductive film 620.

As illustrated in FIG. 18 through FIG. 22 described above, nitride semiconductor light-emitting element 600 according to the present embodiment also achieves the same advantageous effects as nitride semiconductor light-emitting element 100 according to Embodiment 1.

Furthermore, in the present embodiment, since light-transmissive conductive film 620 disposed above P-type cladding layer 610 is included, loss of light propagating above P-type cladding layer 610 can be reduced. As illustrated in FIG. 19, this advantageous effect is particularly pronounced when the thickness of P-type cladding layer 610 is small. In addition, since the thickness of P-type cladding layer 610 can be further reduced, the electrical resistance of nitride semiconductor light-emitting element 600 can be further reduced. As a result, the slope efficiency of nitride semiconductor light-emitting element 600 can be increased and the operating voltage can be reduced.

According to the present embodiment, it is possible to realize nitride semiconductor light-emitting element 600 characterized by effective refractive index difference ΔN of 2.7×10⁻³, position P1 of 15.1 nm, difference ΔP of 5.4 nm, an optical confinement factor into active layer 105 of 1.47%, waveguide loss of 4.0 cm⁻¹, and guide layer free carrier loss of 1.3 cm⁻¹.

### Embodiment 7

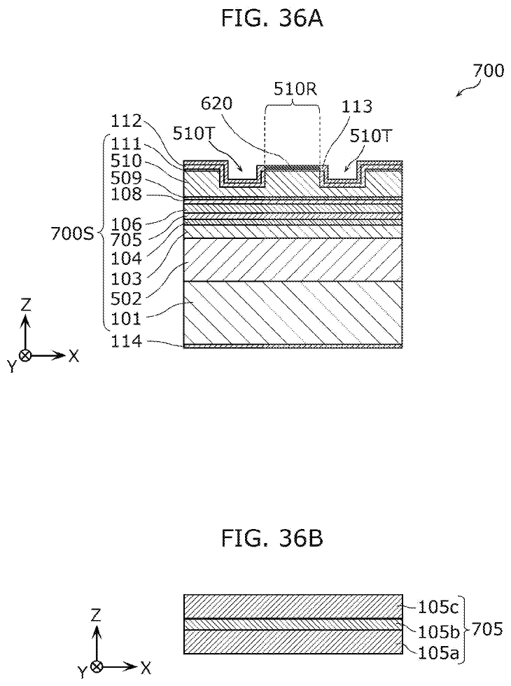

The following describes a nitride semiconductor light-emitting element according to Embodiment 7. The nitride semiconductor light-emitting element according to the present embodiment differs from nitride semiconductor light-emitting element 500 according to Embodiment 5 in regard to the configuration of the active layer. Hereinafter, the nitride semiconductor light-emitting element according to the present embodiment will be described with reference to FIG. 36A and FIG. 36B, focusing on the differences from nitride semiconductor light-emitting element 500 according to Embodiment 5.

FIG. 36A is a schematic cross-sectional view of the overall configuration of nitride semiconductor light-emitting element 700 according to the present embodiment. FIG. 36B is a cross-sectional view illustrating the configuration of active layer 705 included in nitride semiconductor light-emitting element 700 according to the present embodiment.

As illustrated in FIG. 36A, nitride semiconductor light-emitting element 700 according to the present embodiment includes semiconductor stack 700S, current blocking layer 112, P-side electrode 113, N-side electrode 114, and light-transmissive conductive film 620. Semiconductor stack 700S includes substrate 101, N-type first cladding layer 502, N-type second cladding layer 103, N-side guide layer 104, active layer 705, P-side guide layer 106, intermediate layer 108, electron barrier layer 509, P-type cladding layer 510, and contact layer 111.

As illustrated in FIG. 36B, active layer 705 according to the present embodiment has a single quantum well structure, and includes a single well layer 105b and barrier layers 105a and 105c that sandwich well layer 105b. Well layer 105b has the same configuration as well layer 105b according to Embodiment 1, and barrier layers 105a and 105c have the same configuration as barrier layers 105a and 105c according to Embodiment 1.

Nitride semiconductor light-emitting element 700 according to the present embodiment achieves the same advantageous effects as the nitride semiconductor light-emitting element according to Embodiment 5 and the nitride semiconductor light-emitting element according to Embodiment 6. In particular, in nitride semiconductor light-emitting element 700 having a single quantum well structure as described above, active layer 705 includes a single well layer 105b. Thus, even in nitride semiconductor light-emitting element 700 including a small number of well layers 105b with a large refractive index, the peak of the light intensity distribution in the stacking direction can be located in or in the vicinity of active layer 705 owing to the configurations of N-side guide layer 104, P-side guide layer 106, etc. As a result, the optical confinement factor can be increased.

According to the present embodiment, it is possible to realize nitride semiconductor light-emitting element 700 characterized by effective refractive index difference ΔN of 2.9×10⁻³, position P1 of 9.7 nm, difference ΔP of 8.6 nm, an optical confinement factor into active layer 705 of 0.75%, waveguide loss of 3.3 cm⁻¹, and guide layer free carrier loss of 1.4 cm⁻¹. In the present embodiment, since the total thickness of active layer 705 is smaller by 8 nm than active layer 105 according to Embodiment 5, the optical confinement factor is smaller than in Embodiment 5.

### Embodiment 8

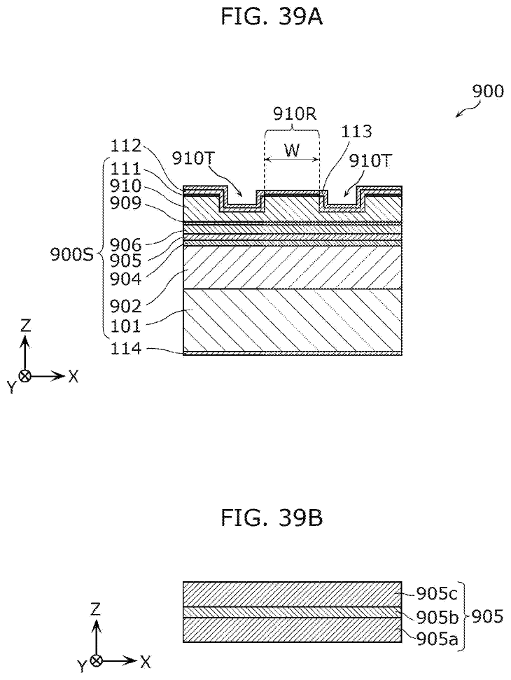

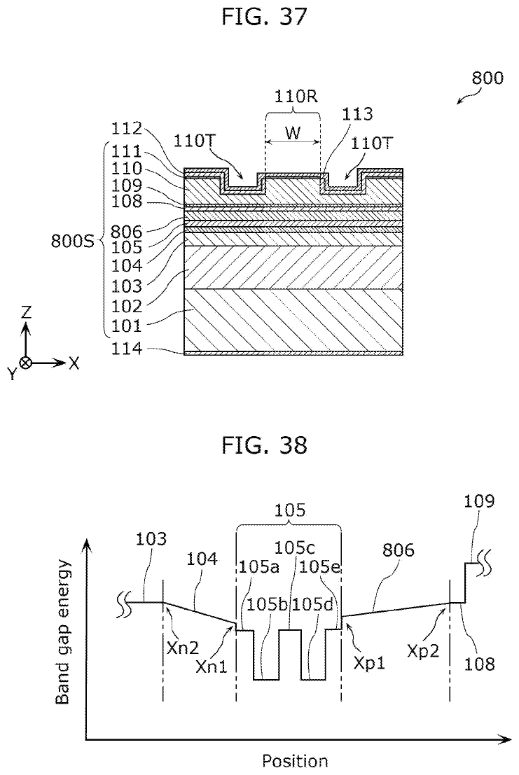

The following describes a nitride semiconductor light-emitting element according to Embodiment 8. The nitride semiconductor light-emitting elements according to the present embodiment is different from nitride semiconductor light-emitting element 100 according to Embodiment 1 in that the average band gap energy of the P-side guide layer is larger than the average band gap energy of the N-side guide layer. Hereinafter, the nitride semiconductor light-emitting element according to the present embodiment will be described with reference to FIG. 37 and FIG. 38, focusing on the differences from nitride semiconductor light-emitting element 100 according to Embodiment 1.

FIG. 37 is a schematic cross-sectional view of the overall configuration of nitride semiconductor light-emitting element 800 according to the present embodiment. FIG. 38 is a schematic graph illustrating a band gap energy distribution in active layer 105 and layers in the vicinity thereof in nitride semiconductor light-emitting element 800 according to the present embodiment.

As illustrated in FIG. 37, nitride semiconductor light-emitting element 800 according to the present embodiment includes semiconductor stack 800S, current blocking layer 112, P-side electrode 113, and N-side electrode 114. Semiconductor stack 800S includes substrate 101, N-type first cladding layer 102, N-type second cladding layer 103, N-side guide layer 104, active layer 105, P-side guide layer 806, intermediate layer 108, electron barrier layer 109, P-type cladding layer 110, and contact layer 111.

In the present embodiment, P-side guide layer 806 is an undoped In_{Xp}Ga_{1-Xp}N layer with a thickness of 280 nm. More specifically, the composition of P-side guide layer 806 at and in the vicinity of the interface closer to active layer 105 is In_{0.03}Ga_{0.97}N, and the composition at and in the vicinity of the interface farther from active layer 105 is GaN. In composition ratio Xp of P-side guide layer 806 decreases at a constant change rate with increasing distance from active layer 105.

As described above, the average value of the In composition ratio of P-side guide layer 806 according to the present embodiment is less than the average value of the In composition ratio of N-side guide layer 104. Accordingly, the average band gap energy of P-side guide layer 806 is larger than the average band gap energy of N-side guide layer 104 (see FIG. 38). In other words, the average refractive index of P-side guide layer 806 is less than the average refractive index of N-side guide layer 104. Here, since the thickness of P-side guide layer 806 is larger than the thickness of N-side guide layer 104, the peak of the light intensity distribution can be shifted toward P-side guide layer 806 with respect to active layer 105. The average refractive index of P-side guide layer 806 is less than the average refractive index of N-side guide layer 104 according to the present embodiment. As a result, it is possible to inhibit the peak of the light intensity distribution from shifting toward P-side guide layer 806 with respect to active layer 105.

The In composition ratio of P-side guide layer 806 continuously and monotonically decreases with increasing distance from active layer 105. In other words, the refractive index of P-side guide layer 806 continuously and monotonically increases with decreasing distance from active layer 105. Accordingly, the peak of the light intensity distribution in the stacking direction can be located closer to active layer 105.

According to the present embodiment, it is possible to realize nitride semiconductor light-emitting element 800 characterized by effective refractive index difference ΔN of 2.8×10⁻³, position P1 of 9.9 nm, position P2 of 2.1 nm, difference ΔP of 7.8 nm, an optical confinement factor into active layer 105 of 1.42%, waveguide loss of 3.4 cm⁻¹, and guide layer free carrier loss of 1.30 cm⁻¹. As described above, in nitride semiconductor light-emitting element 800 according to the present embodiment, the average band gap energy of P-side guide layer 806 is larger than the average band gap energy of N-side guide layer 104, and thus it is possible to locate the peak of the light intensity distribution in the stacking direction closer to the position in the vicinity of the center of active layer 105 in the stacking direction as compared with nitride semiconductor light-emitting element 100 according to Embodiment 1.

### Embodiment 9

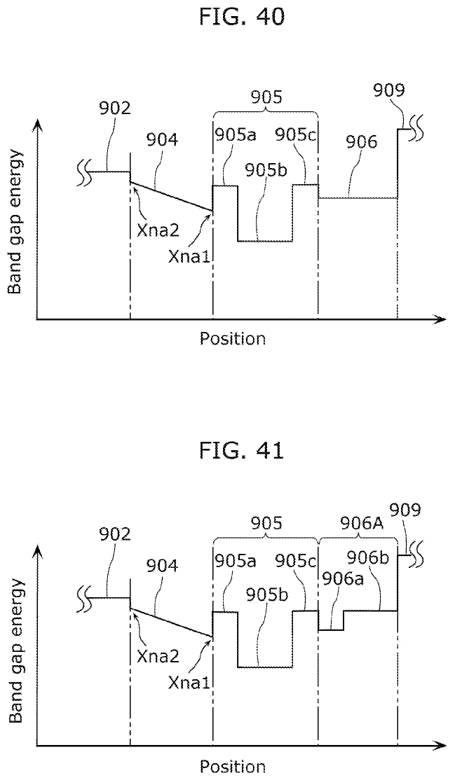

The following describes a nitride semiconductor light-emitting element according to Embodiment 9. The nitride semiconductor light-emitting element according to the present embodiment differs from nitride semiconductor light-emitting element 100 according to Embodiment 1 mainly in regard to the wavelength band of emitted light. Hereinafter, the nitride semiconductor light-emitting element according to the present embodiment will be described with reference to FIG. 39A, FIG. 39B, and FIG. 40, focusing on the differences from nitride semiconductor light-emitting element 100 according to Embodiment 1.

FIG. 39A is a schematic cross-sectional view of the overall configuration of nitride semiconductor light-emitting element 900 according to the present embodiment. FIG. 39B is a schematic cross-sectional view illustrating the configuration of active layer 905 included in nitride semiconductor light-emitting element 900 according to the present embodiment. FIG. 40 is a schematic graph illustrating a band gap energy distribution in active layer 905 and each layer in the vicinity thereof in nitride semiconductor light-emitting element 900 according to the present embodiment.

As illustrated in FIG. 39A, nitride semiconductor light-emitting element 900 according to the present embodiment includes semiconductor stack 900S, current blocking layer 112, P-side electrode 113, and N-side electrode 114. Semiconductor stack 900S includes substrate 101, N-type first cladding layer 902, N-side guide layer 904, active layer 905, P-side guide layer 906, electron barrier layer 909, P-type cladding layer 910, and contact layer 111.

N-type first cladding layer 902 according to the present embodiment is an N-type Al_{0.10}Ga_{0.90}N layer with a thickness of 740 nm. N-type first cladding layer 902 is doped with Si at a concentration of 5×10¹⁷ cm⁻³ as an impurity.

N-side guide layer 904 according to the present embodiment is an N-type Al_{Xna}Ga_{1-Xna}N layer with a thickness of 130 nm. N-side guide layer 904 is doped with Si at a concentration of 5×10¹⁷ cm⁻³ as an impurity. More specifically, the composition of N-side guide layer 904 at and in the vicinity of the interface closer to active layer 905 is Al_{Xna1}Ga_{1-Xna1}N, and the composition at and in the vicinity of the interface farther from active layer 905 is Al_{Xna2}Ga_{1-Xna2}N. In the present embodiment, Al composition ratio Xna1 of N-side guide layer 904 at and in the vicinity of the interface closer to active layer 905 is 0, and Al composition ratio Xna2 of N-side guide layer 904 at and in the vicinity of the interface farther from active layer 905 is 0.06 (i.e., 6%). Al composition ratio Xna of N-side guide layer 904 increases at a constant change rate with increasing distance from active layer 905.

As illustrated in FIG. 39B, active layer 905 according to the present embodiment includes well layer 905b and barrier layers 905a and 905c.

Barrier layer 905a is disposed above N-side guide layer 904 and functions as a barrier in the quantum well structure. In the present embodiment, barrier layer 905a is an undoped Al_{0.05}Ga_{0.95}N layer with a thickness of 11 nm.

Well layer 905b is disposed above barrier layer 905a and functions as a well in the quantum well structure. Well layer 905b is disposed between barrier layer 905a and barrier layer 905c. In the present embodiment, well layer 905b is an undoped In_{0.01}Ga_{0.99}N layer with a thickness of 17.5 nm.

Barrier layer 905c is disposed above well layer 905b and functions as a barrier in the quantum well structure. In the present embodiment, barrier layer 905c is an undoped Al_{0.05}Ga_{0.95}N layer with a thickness of 11 nm.

Nitride semiconductor light-emitting element 900 according to the present embodiment includes active layer 905 having a configuration as described above, and thus is capable of emitting light with a wavelength of at least 350 nm and at most 390 nm

P-side guide layer 906 according to the present embodiment is an undoped Al_{0.05}Ga_{0.95}N layer with a thickness of 280 nm.

Electron barrier layer 909 according to the present embodiment is a P-type Al_{0.36}Ga_{0.64}N layer with a thickness of 5 nm. Electron barrier layer 909 is doped with Mg at a concentration of 1×10¹⁹ cm⁻³ as an impurity.

P-type cladding layer 910 according to the present embodiment is disposed between electron barrier layer 909 and contact layer 111. P-type cladding layer 910 is a layer with a smaller refractive index and a larger band gap energy than those of active layer 905. In the present embodiment, P-type cladding layer 910 is a P-type Al_{0.10}Ga_{0.90}N layer with a thickness of 660 nm. P-type cladding layer 910 is doped with Mg as an impurity. The impurity concentration of P-type cladding layer 910 is lower at the end portion on the side closer to active layer 905 than at the end portion on the side farther from active layer 905. More specifically, P-type cladding layer 910 includes a 250 nm thick P-type Al_{0.10}Ga_{0.90}N layer doped with Mg at a concentration of 2×10¹⁸ cm⁻³ arranged on the side closer to active layer 905, and a 410 nm thick P-type Al_{0.10}Ga_{0.90}N layer doped with Mg at a concentration of 1×10¹⁹ cm arranged on the side farther from active layer 905.

Ridge 910R is formed in P-type cladding layer 910 as with nitride semiconductor light-emitting element 100 according to Embodiment 1. Two trenches 910T disposed along ridge 910R and extending in the Y-axis direction are also formed in P-type cladding layer 910. In the present embodiment, thickness dc of P-type cladding layer 910 at the bottom edge of ridge 910R is 30 nm.

As described above, in nitride semiconductor light-emitting element 900 according to the present embodiment, Al composition ratio Xna of N-side guide layer 904 monotonically increases with increasing distance from active layer 905. In other words, the refractive index of N-side guide layer 904 monotonically increases with decreasing distance from active layer 905. As a result, the peak of the light intensity distribution in the stacking direction can be located closer to active layer 905.

In addition, in the present embodiment, the thickness of P-side guide layer 906 is larger than the thickness of N-side guide layer 904. Accordingly, distance dp between the bottom edge of ridge 910R and active layer 905 is larger as compared to the case where the thickness of P-side guide layer 906 is less than or equal to the thickness of N-side guide layer 904, and thus it is possible to reduce effective refractive index difference ΔN. As a result, it is possible to improve the stability of light output of nitride semiconductor light-emitting element 900.

In addition, in the present embodiment, the Al composition ratio of P-side guide layer 906 is larger than the average Al composition ratio of N-side guide layer 904. In other words, the average band gap energy of P-side guide layer 906 is larger than the average band gap energy of N-side guide layer 904 (see FIG. 40). As a result, the average refractive index of P-side guide layer 906 is less than the average refractive index of N-side guide layer 904. Since the thickness of P-side guide layer 906 is larger than the thickness of N-side guide layer 904 as described above, the peak of the light intensity distribution can be shifted toward P-side guide layer 906 with respect to active layer 905. The average refractive index of P-side guide layer 906 is less than the average refractive index of N-side guide layer 904 according to the present embodiment. As a result, it is possible to inhibit the peak of the light intensity distribution from shifting toward P-side guide layer 906 with respect to active layer 905.

In the present embodiment, it is possible to reduce the series resistance of nitride semiconductor light-emitting element 900 by doping N-side guide layer 904 with an n-type impurity, in the same manner as Embodiment 1. Moreover, in the present embodiment, as illustrated in FIG. 40, the minimum band gap energy of N-side guide layer 904 (i.e., band gap energy of N-side guide layer 904 at and in the vicinity of the interface with active layer 905) is less than a band gap energy of barrier layer 905a. As described above, even when the band gap energy of N-side guide layer 904 at and in the vicinity of the interface with active layer 905 is less than a band gap energy of barrier layer 905a, it is possible to inhibit an increase in hole concentration in N-side guide layer 904, by doping N-side guide layer 904 with an n-type impurity. As a result, the non-radiative recombination probability between electrons and holes in N-side guide layer 904 can be reduced, and thus it is possible to inhibit a decrease in luminescence efficiency and long-term reliability of nitride semiconductor light-emitting element 900.

Furthermore, with nitride semiconductor light-emitting element 900 according to the present embodiment, even when the wavelength corresponding to an energy difference between base quantum levels of electrons and holes is less than or equal to 380 nm, since barrier layers 905a and 905c are formed of an Al_{0.05}Ga_{0.95}N layer with an Al composition of at least 0.04, a band gap energy of barrier layer 905a and a band gap energy of barrier layer 905c are larger than or equal to 3.47 eV, and are sufficiently larger than energy of 3.28 eV corresponding to wavelength 375 nm. As a result, it is possible to easily form the quantum level with an emission wavelength in the 375 nm band in well layer 905b. In addition, since electrons and holes can be confined to a quantum level in the quantum well region, it is possible to inhibit electrons and holes in the quantum well region from leaking to N-side guide layer 904 and P-side guide layer 906. It is thus possible to improve the luminescence efficiency of nitride semiconductor light-emitting element 900, which in turn improves the temperature characteristics of nitride semiconductor light-emitting element 900.

According to the present embodiment, it is possible to realize nitride semiconductor light-emitting element 900 characterized by effective refractive index difference ΔN of 2.2×10⁻³, position P1 of 2.9 nm, position P2 of 2.3 nm, difference ΔP of 0.6 nm, an optical confinement factor into active layer 905 of 6.7%, and waveguide loss of 2.8 cm⁻¹.

The following describes the characteristics of nitride semiconductor light-emitting elements according to Comparative Examples 9, 10, and 3, for explaining the advantageous effects of nitride semiconductor light-emitting element 900 according to the present embodiment.

The nitride semiconductor light-emitting elements according to Comparative Example 9 and Comparative Example 10 match nitride semiconductor light-emitting element 900 according to the present embodiment in points other than that the Al composition ratios of P-side guide layers are 3% and 2%, respectively. In the nitride semiconductor light-emitting element according to Comparative Example 9, an average band gap energy of a P-side guide layer is identical to an average band gap energy of N-side guide layer 904. In the nitride semiconductor light-emitting element according to Comparative Example 10, an average band gap energy of a P-side guide layer is less than an average band gap energy of N-side guide layer 904.

In the nitride semiconductor light-emitting element according to Comparative Example 9, effective refractive index difference ΔN is 1.8×10⁻³, position P1 is 10.8 nm, position P2 is 9.9 nm, difference ΔP is 0.9 nm, an optical confinement factor into active layer 905 is 5.7%, and waveguide loss is 3.2 cm⁻¹. In the nitride semiconductor light-emitting element according to Comparative Example 10, effective refractive index difference ΔN is 3.1×10⁻³, position P1 is 80.4 nm, position P2 is 68.9 nm, difference ΔP is 11.5 nm, an optical confinement factor into active layer 905 is 4.7%, and waveguide loss is 3.5 cm⁻¹.

As described above, in the present embodiment, the average band gap energy of the P-side guide layer is larger than the average band gap energy of N-side guide layer 904, and thus it is possible to further improve the optical confinement factor, the waveguide loss, and the peak position of light intensity distribution as compared with the nitride semiconductor light-emitting element according to Comparative Example 9 and Comparative Example 10.

The nitride semiconductor light-emitting element according to Comparative Example 3 match nitride semiconductor light-emitting element 900 according to the present embodiment in points other than that the composition of N-side guide layer is uniform. The N-side guide layer of the nitride semiconductor light-emitting element according to Comparative Example 3 is an N-type Al_{0.03}Ga_{0.97}N layer with a thickness of 130 nm. The N-side guide layer is doped with Si at a concentration of 5×10¹⁷ cm⁻³ as an impurity.

In the nitride semiconductor light-emitting element according to Comparative Example 3, effective refractive index difference ΔN is 4.1×10⁻³, position P1 is 49.5 nm, position P2 is 35.7 nm, difference ΔP is 13.8 nm, an optical confinement factor into active layer 905 is 5.0%, and waveguide loss is 3.4 cm⁻¹.

As described above, according to the present embodiment, since the band gap energy of N-side guide layer 904 continuously and monotonically increases with increasing distance from active layer 905, it is possible to further improve the effective refractive index difference ΔN, the optical confinement factor, and the peak position of light intensity distribution, as compared with the nitride semiconductor light-emitting element according to Comparative Example 3.

### Variation 1 of Embodiment 9

The following describes a nitride semiconductor light-emitting element according to Variation 1 of Embodiment 9. The nitride semiconductor light-emitting element according to the present variation matches nitride semiconductor light-emitting element 900 according to Embodiment 9 in points other than the band gap energy distribution of a P-side guide layer in the stacking direction. The nitride semiconductor light-emitting element according to the present variation will be described with reference to FIG. 41. FIG. 41 is a schematic graph illustrating a band gap energy distribution in active layer 905 and layers in the vicinity thereof in the nitride semiconductor light-emitting element according to the present variation.

As illustrated in FIG. 41, P-side guide layer 906A of the nitride semiconductor light-emitting element according to the present variation includes P-side first guide layer 906a and P-side second guide layer 906b. P-side first guide layer 906a is a guide layer disposed above active layer 905. P-side second guide layer 906b is a guide layer that is disposed above P-side first guide layer 906a and has a band gap energy larger than a band gap energy of P-side first guide layer 906a. In the present embodiment, P-side first guide layer 906a is an undoped Al_{0.01}Ga_{0.99}N layer with a thickness of 70 nm, and P-side second guide layer 906b is an undoped Al_{0.05}Ga_{0.95}N layer with a thickness of 210 nm. As described above, P-side first guide layer 906a has an Al composition ratio greater than that of P-side second guide layer 906b.

The nitride semiconductor light-emitting element according to the present variation achieves the same advantageous effects as nitride semiconductor light-emitting element 900 according to Embodiment 9. In addition, the Al composition ratio of P-side guide layer 906A increases stepwise with increasing distance from active layer 905. In this manner, the refractive index of P-side guide layer 906A in a region closer to active layer 905 can be further improved as compared with a region farther from active layer 905, and thus it is possible to locate the peak of the light intensity distribution closer to active layer 905.

According to the present variation, it is possible to realize a nitride semiconductor light-emitting element characterized by effective refractive index difference ΔN of 1.24×10⁻³, position P1 of 11.6 nm, position P2 of 11.3 nm, difference ΔP of 0.3 nm, an optical confinement factor into active layer 905 of 7.7%, and waveguide loss of 2.5 cm⁻¹.

The following describes the characteristics of nitride semiconductor light-emitting elements according to Comparative Example 11 and Comparative Example 12, for explaining the advantageous effects of the nitride semiconductor light-emitting element according to the present variation.

The nitride semiconductor light-emitting elements according to Comparative Example 11 and Comparative Example 12 match nitride semiconductor light-emitting element 900 according to the present variation in points other than that the Al composition ratios of P-side second guide layers are 3.67% and 2.3%, respectively. In the nitride semiconductor light-emitting element according to Comparative Example 11, an average band gap energy of a P-side guide layer is identical to an average band gap energy of N-side guide layer 904. In the nitride semiconductor light-emitting element according to Comparative Example 12, an average band gap energy of a P-side guide layer is less than an average band gap energy of N-side guide layer 904.

In the nitride semiconductor light-emitting element according to Comparative Example 11, effective refractive index difference ΔN is 1.7×10⁻³, position P1 is 34.8 nm, position P2 is 33.3 nm, difference ΔP is 1.5 nm, an optical confinement factor into active layer 905 is 6.8%, and waveguide loss is 2.8 cm⁻¹. In the nitride semiconductor light-emitting element according to Comparative Example 12, effective refractive index difference ΔN is 2.5×10⁻³, position P1 is 60.1 nm, position P2 is 56.6 nm, difference ΔP is 3.5 nm, an optical confinement factor into active layer 905 is 5.4%, and waveguide loss is 3.3 cm⁻¹.

As described above, in the present variation, the average band gap energy of P-side guide layer 906A is larger than the average band gap energy of N-side guide layer 904, and thus it is possible to further improve the optical confinement factor, the waveguide loss, and the peak position of light intensity distribution as compared with the nitride semiconductor light-emitting element according to Comparative Example 11 and Comparative Example 12.

### Variation 2 of Embodiment 9

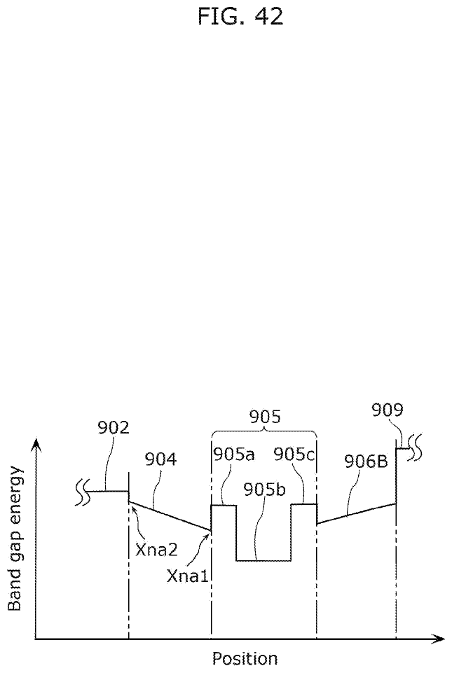

The following describes a nitride semiconductor light-emitting element according to Variation 2 of Embodiment 9. The nitride semiconductor light-emitting element according to the present variation matches nitride semiconductor light-emitting element 900 according to Embodiment 9 in points other than the band gap energy distribution of a P-side guide layer in the stacking direction. The nitride semiconductor light-emitting element according to the present variation will be described with reference to FIG. 42. FIG. 42 is a schematic graph illustrating a band gap energy distribution in active layer 905 and layers in the vicinity thereof in the nitride semiconductor light-emitting element according to the present variation.

P-side guide layer 906B according to the present variation is an undoped Al_{Xpa}Ga_{1-Xpa}N layer with a thickness of 280 nm. More specifically, the composition of P-side guide layer 906B at and in the vicinity of the interface closer to active layer 905 is GaN, and the composition at and in the vicinity of the interface farther from active layer 905 is Al_{0.08}Ga_{0.92}N. Al composition ratio Xpa of P-side guide layer 906B increases at a constant change rate with increasing distance from active layer 905. Accordingly, the band gap energy of P-side guide layer 906B continuously and monotonically increases with increasing distance from active layer 905.

The nitride semiconductor light-emitting element according to the present variation achieves the same advantageous effects as nitride semiconductor light-emitting element 900 according to Embodiment 9. In addition, the Al composition ratio of P-side guide layer 906B continuously and monotonically increases with increasing distance from active layer 905. In this manner, since the refractive index of P-side guide layer 906B increases with decreasing distance from active layer 905, it is possible to locate the peak of the light intensity distribution closer to active layer 905.

According to the present variation, it is possible to realize a nitride semiconductor light-emitting element characterized by effective refractive index difference ΔN of 1.13×10⁻³, position P1 of 22.2 nm, position P2 of 21.3 nm, difference ΔP of 0.9 nm, an optical confinement factor into active layer 905 of 7.3%, and waveguide loss of 2.6 cm⁻¹.

The following describes the characteristics of nitride semiconductor light-emitting elements according to Comparative Example 13 and Comparative Example 14, for explaining the advantageous effects of the nitride semiconductor light-emitting element according to the present variation.

The nitride semiconductor light-emitting elements according to Comparative Example 13 and Comparative Example 14 match the nitride semiconductor light-emitting element according to present variation in points other than that the Al composition ratios of P-side guide layers at an interface on the side farther from active layer 905 are 6% and 4%, respectively. In the nitride semiconductor light-emitting element according to Comparative Example 13, an average band gap energy of a P-side guide layer is identical to an average band gap energy of N-side guide layer 904. In the nitride semiconductor light-emitting element according to Comparative Example 14, an average band gap energy of a P-side guide layer is less than an average band gap energy of N-side guide layer 904.

In the nitride semiconductor light-emitting element according to Comparative Example 13, effective refractive index difference ΔN is 1.43×10⁻³, position P1 is 36.4 nm, position P2 is 34.9 nm, difference ΔP is 1.5 nm, an optical confinement factor into active layer 905 is 6.6%, and waveguide loss is 2.8 cm⁻¹. In the nitride semiconductor light-emitting element according to Comparative Example 14, effective refractive index difference ΔN is 1.9×10⁻³, position P1 is 54.6 nm, position P2 is 52.3 nm, difference ΔP is 2.3 nm, an optical confinement factor into active layer 905 is 5.7%, and waveguide loss is 3.1 cm⁻¹.

As described above, in the present variation, the average band gap energy of P-side guide layer 906B is larger than the average band gap energy of N-side guide layer 904, and thus it is possible to further improve the optical confinement factor, the waveguide loss, and the peak position of light intensity distribution as compared with the nitride semiconductor light-emitting element according to Comparative Example 13 and Comparative Example 14.

### Variations and Others

Although the nitride semiconductor light-emitting element according to the present disclosure has been described based on embodiments, the present disclosure is not limited to the above embodiments.

For example, each of the above embodiments gives an example in which the nitride semiconductor light-emitting element is a semiconductor laser element, but the nitride semiconductor light-emitting element is not limited to a semiconductor laser element. For example, the nitride semiconductor light-emitting element may be a superluminescent diode. In such cases, the reflectance of the end face of the semiconductor stack included in the nitride semiconductor light-emitting element with respect to the light emitted from the semiconductor stack may be 0.1% or less. For example, such reflectance can be achieved by forming an anti-reflective film including, for example, a dielectric multilayer film on the end face. Alternatively, if the ridge that serves as the waveguide is inclined at an angle of 5° or more from the normal direction of the front end face and intersects the front end face in an inclined stripe structure, the ratio of the component of guided light reflected off the front end face that combines with the waveguide and becomes guided light again can be reduced to a small value of 0.1% or less. In particular, if the wavelength of emitted light is caused to fall within a band from 430 nm to 455 nm, the thickness of each of well layers 105b and 105d of active layer 105 is less than or equal to 35 Å. In this case, even when a reflectance of the end face is reduced, light amplification gain can be ensured owing to the effects on reduction in waveguide loss and effects on an increase in an optical confinement factor into active layer 105, which are yielded by the nitride semiconductor light-emitting element according to the present disclosure. If such a nitride semiconductor light-emitting element is provided inside an external resonator that includes a wavelength selection element, self-heating of the nitride semiconductor light-emitting element can be reduced, and a change in wavelength of emitted light can be inhibited, and thus oscillation at a desired selected wavelength can be more readily achieved.

In Embodiments 1 through 6, in the nitride semiconductor light-emitting element, active layer 105 has a structure including two well layers, but active layer 105 may have a structure including only a single well layer. In this manner, also when the active layer includes only a single well layer having a high refractive index, controllability of a position in light intensity distribution in the stacking direction can be enhanced if the N-side guide layer and the P-side guide layer according to the present disclosure are used, and thus it is possible to locate a peak of the light intensity distribution in the stacking direction in the well layer or in the vicinity thereof. As a result, a nitride semiconductor light-emitting element with a low oscillation threshold, low waveguide loss, a high optical confinement factor, and current-light output (IL) characteristics with excellent linearity can be realized.

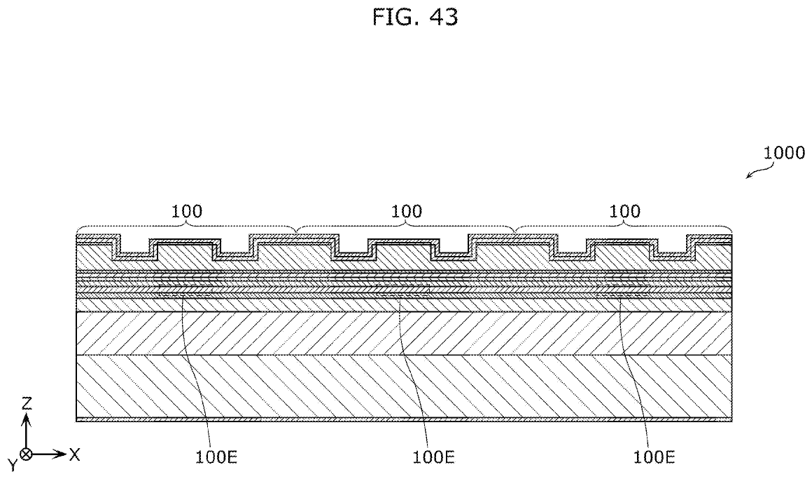

In each of the above embodiments, the nitride semiconductor light-emitting element is exemplified as including a single ridge, but the nitride semiconductor light-emitting element may include a plurality of ridges. Such a nitride semiconductor light-emitting element will be described with reference to FIG. 43. FIG. 43 is a schematic cross-sectional view of the overall configuration of nitride semiconductor light-emitting element 1000 according to Variation 1. As illustrated in FIG. 43, nitride semiconductor light-emitting element 1000 according to Variation 1 has a configuration in which a plurality of nitride semiconductor light-emitting elements 100 according to Embodiment 1 are linearly arrayed in the horizontal direction. In FIG. 43, nitride semiconductor light-emitting element 1000 has a configuration in which three nitride semiconductor light-emitting elements 100 are integrally arrayed, but the number of nitride semiconductor light-emitting elements 100 included in nitride semiconductor light-emitting element 1000 is not limited to three. The number of nitride semiconductor light-emitting elements 100 included in nitride semiconductor light-emitting element 1000 may be two or more. Each nitride semiconductor light-emitting element 100 includes light-emitting portion 100E that emits light. Light-emitting portion 100E is the portion of active layer 105 that emits light, and corresponds to the portion of active layer 105 located below ridge 110R. Thus, nitride semiconductor light-emitting element 1000 according to Variation 1 includes a plurality of linearly arrayed light-emitting portions 100E. With this configuration, a plurality of beams of emitted light can be obtained from a single nitride semiconductor light-emitting element 1000, and thus it is possible to realize a high-output nitride semiconductor light-emitting element 1000. In Variation 1, although nitride semiconductor light-emitting element 1000 includes a plurality of nitride semiconductor light-emitting elements 100, the plurality of nitride semiconductor light-emitting elements that nitride semiconductor light-emitting element 1000 includes is not limited to this example; nitride semiconductor light-emitting element 1000 may include nitride semiconductor light-emitting elements according to any other embodiment.

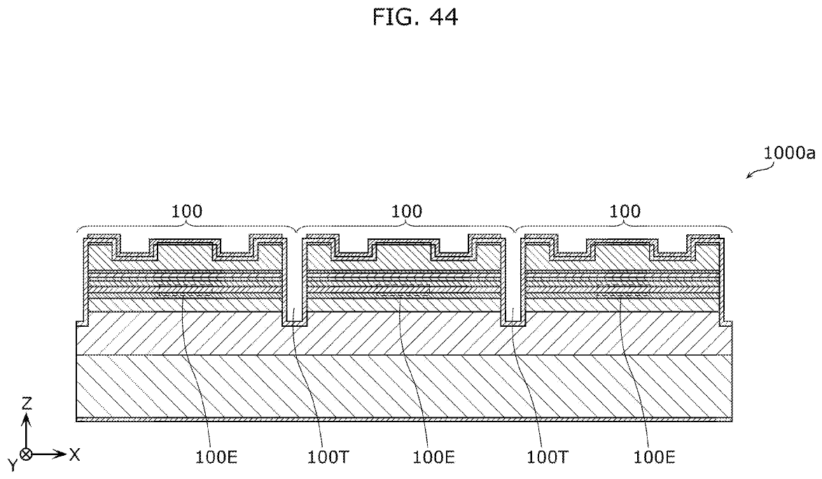

As in nitride semiconductor light-emitting element 1000a according to Variation 2 illustrated in FIG. 44, individual light-emitting portions 100E may be separated by isolation trench 100T having a width (a dimension in the X-axis direction) of at least 8 μm and at most 20 μm, and a depth (a dimension in the Z-axis direction) of at least 1.0 μm and at most 1.5 μm. By adopting such a structure, thermal interference due to self-heating during operation of individual light-emitting portions 100E can be reduced even when the distance between adjacent light-emitting portions 100E is as small as 300 μm or less.

Since ΔN in the nitride semiconductor light-emitting element according to the present disclosure is small and the horizontal divergence angle can be reduced, even when the distance between the centers of light-emitting portions 100E illustrated in FIG. 43 and FIG. 44 is small, the light emitted from individual light-emitting portions 100E is not likely to interfere with each other, and thus the distance between the centers of light-emitting portions 100E can be as small as 250 μm or less. In Variation 2, the distance is 225 μm.

Although the guide layers are each an In_{Xn}Ga_{1-Xn}N layer in the above-described embodiments and variations, the composition of each of the guide layers is not limited to this composition. For example, if the Al composition ratio of the N-side guide layer is Xna and the Al composition ratio of the P-side guide layer is Xpa, the composition of the N-side guide layer may be Al_{Xna}Ga_{1-Xna}N and the composition of the N-side guide layer may be Al_{Xpa}Ga_{1-Xpa}N. In this case, the Al composition ratio of N-side guide layer may continuously and monotonically increases with increasing distance from the active layer, and the average value of the Al composition ratio of the N-side guide layer may be smaller than the average value of the Al composition ratio of the P-side guide layer. A nitride semiconductor light-emitting element having such a configuration can also reduce an operating voltage and increase an optical confinement factor into the active layer. The absolute value of the average change rate of the Al composition ratio in the stacking direction in the region from the interface on the side closer to the active layer of the N-side guide layer to the central portion of the N-side guide layer in the stacking direction may be smaller than the absolute value of the average change rate of the Al composition ratio in the stacking direction in the region from the central portion to the interface on the side closer to the N-type first cladding layer of the N-side guide layer.

In each of the embodiments, the nitride semiconductor light-emitting element is exemplified as including N-type second cladding layer 103, intermediate layer 108, electron barrier layer 109, and current blocking layer 112, but the nitride semiconductor light-emitting element does not necessarily need to include these layers.

Although P-type cladding layers 110, 510, and 610 are each a layer with a uniform Al composition ratio, the configuration of each of the P-type cladding layers is not limited to this configuration. For example, each of the P-type cladding layers may have a superlattice configuration in which a plurality of AlGaN layers and a plurality of GaN layers are alternately stacked. More specifically, each of the P-type cladding layers may have a superlattice configuration in which, for example, 1.85 nm thick AlGaN layers with an Al composition ratio of 0.052 (5.2%) and 1.85 nm thick GaN layers are alternately stacked In this case, the Al composition ratio of each of the P-type cladding layers is defined by an average Al composition ratio of 0.026 (2.6%) in the superlattice configuration.

Although an N-type GaN substrate is used as substrate 101 in the above-described embodiments, an N-type AlGaN substrate may be used. By using the N-type AlGaN substrate, especially in Embodiment 9, the tensile strain of each cladding layer including AlGaN with a high Al composition ratio can be reduced, and thus it is possible to inhibit the occurrence of defects such as cracks in the semiconductor stack. In this case, the Al composition ratio of the N-type AlGaN substrate may be greater than zero and less than the Al composition ratio of each guide layer including AlGaN. Alternatively, the Al composition ratio of the N-type AlGaN substrate may be between the Al composition ratio of each guide layer including AlGaN and each cladding layer including AlGaN. When the Al composition ratio of the N-type AlGaN substrate is between the Al composition ratio of each guide layer including AlGaN and each cladding layer including AlGaN, the Al composition ratio of the N-type AlGaN substrate may be closer to the Al composition ratio of each cladding layer including AlGaN than to the Al composition ratio of each guide layer including AlGaN. Alternatively, the Al composition ratio of the N-type AlGaN substrate may be greater than the Al composition ratio of each cladding layer including N-type AlGaN. When the Al composition ratio of the N-type AlGaN substrate is greater than the Al composition ratio of the cladding layer including N-type AlGaN, leakage of light to substrate 101 can be reduced.

In addition, forms obtained by various modifications to the respective exemplary embodiments described above that can be conceived by a person of skill in the art as well as forms realized by arbitrarily combining structural components and functions in the respective exemplary embodiments described above which are within the scope of the essence of the present disclosure are also included in the present disclosure.

For example, the configuration of each cladding layer according to Embodiment 1 may be applied to the nitride semiconductor light-emitting elements according to Embodiments 5 and 6. As another example, the light-transmissive conductive film according to Embodiment 6 may be applied to the nitride semiconductor light-emitting elements of Embodiments 1 through Embodiment 5.

### INDUSTRIAL APPLICABILITY

The nitride semiconductor light-emitting element according to the present disclosure can be applied to, for example, a light source for processing machines, as a high-output, high-efficiency light source.

1. A nitride semiconductor light-emitting element that comprises a semiconductor stack and emits light from an end face of the semiconductor stack, the end face being perpendicular to a stacking direction of the semiconductor stack, wherein
the semiconductor stack includes:
an N-type first cladding layer;
an N-side guide layer disposed above the N-type first cladding layer;
an active layer that is disposed above the N-side guide layer, includes a well layer and a barrier layer, and has a quantum well structure;
a P-side guide layer disposed above the active layer;
an electron barrier layer disposed above the P-side guide layer; and
a P-type cladding layer disposed above the electron barrier layer,
the P-side guide layer is an undoped layer,
a band gap energy of the N-side guide layer monotonically increases with increasing distance from the active layer,
the N-side guide layer includes a portion in which the band gap energy continuously increases with increasing distance from the active layer,
an average band gap energy of the P-side guide layer is larger than or equal to an average band gap energy of the N-side guide layer,
Tn<Tp, where Tn is a thickness of the N-side guide layer and Tp is a thickness of the P-side guide layer, and
a band gap energy of the barrier layer is less than or equal to a minimum value of the band gap energy of the N-side guide layer and a minimum value of a band gap energy of the P-side guide layer.

2. The nitride semiconductor light-emitting element according to claim 1, wherein
the N-side guide layer includes In_{Xn}Ga_{1-Xn}N,
the P-side guide layer includes In_{Xp}Ga_{1-Xp}N,
an In composition ratio of the N-side guide layer monotonically decreases with increasing distance from the active layer, and
an average value of the In composition ratio of the N-side guide layer is greater than or equal to an average value of an In composition ratio of the P-side guide layer.

3. The nitride semiconductor light-emitting element according to claim 1, wherein
the N-side guide layer includes Al_{Xna}Ga_{1-Xna}N,
the P-side guide layer includes Al_{Xpa}Ga_{1-Xpa}N,
an Al composition ratio of the N-side guide layer monotonically increases with increasing distance from the active layer, and
an average value of the Al composition ratio of the N-side guide layer is less than or equal to an average value of an Al composition ratio of the P-side guide layer.

4. A nitride semiconductor light-emitting element that comprises a semiconductor stack and emits light from an end face of the semiconductor stack, the end face being perpendicular to a stacking direction of the semiconductor stack, wherein
the semiconductor stack includes:
an N-type first cladding layer;
an N-side guide layer disposed above the N-type first cladding layer;
an active layer that is disposed above the N-side guide layer, includes a well layer and a barrier layer, and has a quantum well structure;
a P-side guide layer disposed above the active layer;
an electron barrier layer disposed above the P-side guide layer; and
a P-type cladding layer disposed above the electron barrier layer,
the P-side guide layer is an undoped layer,
a band gap energy of the N-side guide layer monotonically increases with increasing distance from the active layer, the N-side guide layer includes a portion in which the band gap energy continuously increases with increasing distance from the active layer,
an average band gap energy of the P-side guide layer is larger than an average band gap energy of the N-side guide layer, and
a band gap energy of the barrier layer is less than or equal to a minimum value of the band gap energy of the N-side guide layer and a minimum value of a band gap energy of the P-side guide layer.

5. The nitride semiconductor light-emitting element according to claim 4, wherein
Tn<Tp, where Tn is a thickness of the N-side guide layer and Tp is a thickness of the P-side guide layer.

6. The nitride semiconductor light-emitting element according to claim 4, wherein
the N-side guide layer includes In_{Xn}Ga_{1-Xn}N,
the P-side guide layer includes In_{Xp}Ga_{1-Xp}N,
an In composition ratio of the N-side guide layer monotonically decreases with increasing distance from the active layer, and
an average value of the In composition ratio of the N-side guide layer is greater than an average value of an In composition ratio of the P-side guide layer.

7. The nitride semiconductor light-emitting element according to claim 4, wherein
the N-side guide layer includes Al_{Xna}Ga_{1-Xna}N,
the P-side guide layer includes Al_{Xpa}Ga₁₋ₓₚₐN,
an Al composition ratio of the N-side guide layer monotonically increases with increasing distance from the active layer, and
an average value of the Al composition ratio of the N-side guide layer is less than an average value of an Al composition ratio of the P-side guide layer.

8. The nitride semiconductor light-emitting element according to claim 6, wherein
an absolute value of an average change rate of the In composition ratio of the N-side guide layer in the stacking direction is smaller in a region from an interface of the N-side guide layer on a side closer to the active layer to a central portion of the N-side guide layer in the stacking direction than in a region from the central portion to an interface of the N-side guide layer on a side closer to the N-type first cladding layer.

9. The nitride semiconductor light-emitting element according to claim 7, wherein
an absolute value of an average change rate of the Al composition ratio of the N-side guide layer in the stacking direction is smaller in a region from an interface of the N-side guide layer on a side closer to the active layer to a central portion of the N-side guide layer in the stacking direction than in a region from the central portion to an interface of the N-side guide layer on a side closer to the N-type first cladding layer.

10. The nitride semiconductor light-emitting element according to claim 4, wherein
the barrier layer includes In_{Xb}Ga_{1-Xb}N,
a maximum value of an In composition ratio of the N-side guide layer is less than or equal to an In composition ratio of the barrier layer, and
a maximum value of an In composition ratio of the P-side guide layer is less than or equal to the In composition ratio of the barrier layer.

11. The nitride semiconductor light-emitting element according to claim 4, wherein
the N-side guide layer is doped with an impurity at a concentration of at least 1×10¹⁷ cm⁻³ and at most 6×10¹⁷ cm⁻³.

12. The nitride semiconductor light-emitting element according to claim 4, wherein
a peak of a light intensity distribution in the stacking direction is located in the active layer.

13. The nitride semiconductor light-emitting element according to claim 4, wherein
an impurity concentration of the P-type cladding layer is lower at an end portion on a side closer to the active layer than at an end portion on a side farther from the active layer.

14. The nitride semiconductor light-emitting element according to claim 4, wherein
the electron barrier layer includes an Al composition variation region in which an Al composition ratio monotonically increases with increasing distance from the active layer.

15. The nitride semiconductor light-emitting element according to claim 4, wherein
a ridge is provided in the P-type cladding layer, and a distance between a bottom edge of the ridge and the electron barrier layer is at least 10 nm and at most 70 nm.

16. The nitride semiconductor light-emitting element according to claim 4, wherein
the N-type first cladding layer and the P-type cladding layer include Al, and
Ync>Ypc, where Ync is an Al composition ratio of the N-type first cladding layer and Ypc is an Al composition ratio of the P-type cladding layer.

17. The nitride semiconductor light-emitting element according to claim 4, comprising
a light-transmissive conductive film disposed above the P-type cladding layer.

18. The nitride semiconductor light-emitting element according to claim 4, comprising
an N-type second cladding layer disposed between the N-type first cladding layer and the N-side guide layer, wherein
a band gap energy of the N-type second cladding layer is smaller than a band gap energy of the N-type first cladding layer and larger than or equal to a maximum value of the band gap energy of the P-side guide layer.

19. The nitride semiconductor light-emitting element according to claim 4, comprising
a plurality of light-emitting portions arranged in a linear array.

20. A nitride semiconductor light-emitting element that comprises a semiconductor stack and emits light from an end face of the semiconductor stack, the end face being perpendicular to a stacking direction of the semiconductor stack, wherein
the semiconductor stack includes:
an N-type first cladding layer;
an N-side guide layer disposed above the N-type first cladding layer;
an active layer that is disposed above the N-side guide layer, includes a well layer and a barrier layer, and has a quantum well structure;
a P-side guide layer disposed above the active layer;
an electron barrier layer disposed above the P-side guide layer; and
a P-type cladding layer disposed above the electron barrier layer,
the P-side guide layer is an undoped layer,
a band gap energy of the N-side guide layer monotonically increases with increasing distance from the active layer,
the N-side guide layer includes a portion in which the band gap energy continuously increases with increasing distance from the active layer,
the nitride semiconductor light-emitting element comprises a P-side electrode disposed above the semiconductor stack, and
the P-side electrode includes Ag.

21. The nitride semiconductor light-emitting element according to claim 20, wherein
an average band gap energy of the P-side guide layer is larger than or equal to an average band gap energy of the N-side guide layer.
